(19) United States
(12) Patent Application Publication
(10) Pub. No.: US 2024/0264539 A1
(43) Pub. Date: Aug. 8, 2024

(54) INSPECTION DATA FILTERING SYSTEMS AND METHODS

(71) Applicant: ASML NETHERLANDS B.V., Veldhoven (NL)

(72) Inventors: Lingling LU, San Jose, CA (US); Yuzhang LIN, San Jose, CA (US); Teng WANG, San Jose, CA (US); Bo WANG, Cupertino, CA (US); Raphael Eric LA GRECA, Saint -Egreve (FR); Stefan HUNSCHE, Santa Clara, CA (US)

(73) Assignee: ASML NETHERLANDS B.V., Veldhoven (NL)

(21) Appl. No.: 18/565,951

(22) PCT Filed: May 20, 2022
(86) PCT No.: PCT/EP2022/063752

§ 371 Date: Nov. 30, 2023

Related U.S. Application Data
(60) Provisional application No. 63/212,249, filed on Jun. 18, 2021.
(60) Provisional application No. 63/290,196, filed on Dec. 16, 2021.

(51) Int. Cl. G03F 7/00; G06T 7/00; G06T 7/12

(52) U.S. Cl. CPC G03F 7/706837; G03F 7/70625; G03F 7/70655; G06T 7/0006; G06T 7/12; G06T 2207/10061; G06T 2207/30148

(57) ABSTRACT

To monitor semiconductor manufacturing process variation, contours of identical pattern features are determined based on SEM images, and the contours are aggregated and statistically analyzed to determine the variation of the feature. Some of the contours are outliers, and the aggregation and averaging of the contours “hides” these outliers. The present disclosure describes filtering certain outlier contours before they are aggregated and statistically analyzed. The filtering can be performed at multiple levels, such as based on individual points on the contours in the set of inspection contours, or based on overall geometrical shapes of the contours in the set of inspection contours.

### CROSS-REFERENCE TO RELATED APPLICATIONS

This application claims priority of U.S. applications 63/212,249 which was filed on 18 Jun. 2021 and 63/290,196 which was filed on 16 Dec. 2021 and which are incorporated herein in its entirety by reference.

### TECHNICAL FIELD

The present disclosure relates generally to inspection data filtering associated with semiconductor manufacturing processes.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in defect detection and inspection become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as overlay metrology, it may be desirable to obtain high quality imaging and efficient collection of surface information from secondary electrons and buried layer information from backscattered electrons, simultaneously, highlighting a need for using multiple electron detectors in a SEM. Although multiple electron detectors in various structural arrangements may be used to maximize collection and detection efficiencies of secondary and backscattered electrons individually, the combined detection efficiencies remain low, and therefore, the image quality achieved may be inadequate for high accuracy and high throughput defect inspection and metrology of two-dimensional and three-dimensional structures.

### SUMMARY

To monitor manufacturing process variation, contours of identical pattern features may be determined based on SEM images of substrate patterns. The contours can be aggregated (e.g., stacked) and statistically analyzed to determine the variation of a given feature. Some of the contours are typically outliers, and the aggregating of the contours “hides” these outliers, which may result in reduced accuracy measurement/characterization of certain manufacturing process characteristics, such as critical dimension, edge placement error, or overlay error, among others. The present disclosure describes filtering certain outlier contours before they are aggregated and statistically analyzed. The filtering can be performed at multiple levels, such as based on individual points on the contours in a set of inspection contours, or based on overall geometrical shapes of the contours in the set of inspection contours. This may enhance the accuracy of measurement/characterization of these manufacturing process characteristics, thereby enabling more optimal adjustments to be made to the manufacturing process to increase device yield, or may have other advantages.

According to an embodiment, there is provided a method for enhancing a patterning process. The method comprises receiving substrate pattern inspection images and determining contours in the substrate pattern inspection images to form a set of inspection contours. Determining contours comprises detecting edges of features in the substrate pattern inspection images. The method further comprises filtering outlier contours from the set of inspection contours.

In some embodiments, a determined contour comprises vertices; detecting the edges of the features comprises identifying the vertices in the determined contours; and the filtering of the outlier contours is based on the vertices.

In some embodiments, the method further comprises determining angles formed at vertices of the determined contours, and filtering the outlier contours from the set of inspection contours based on the angles.

In some embodiments, filtering the outlier contours from the set of inspection contours is based on comparisons of the determined angles to an angle threshold, and determined contours with an angle at a vertex smaller than the angle threshold are determined to be outlier contours and filtered from the set of inspection contours. In some embodiments, the threshold angle is 120, 90, 60, or 45 degrees.

In some embodiments, the method further comprises determining distances between adjacent vertices of the determined contours, and filtering the outlier contours from the set of inspection contours based on the distances.

In some embodiments, filtering the outlier contours from the set of inspection contours is based on comparisons of the determined distances to a distance threshold, and determined contours with a distance that breaches the distance threshold are determined to be outlier contours and filtered from the set of inspection contours.

In some embodiments, the distance threshold comprises: a distance that is a given number of times, or a percentage, larger or smaller than an average distance between vertices; or a distance that corresponds to a contour edge roughness parameter.

In some embodiments, the method further comprises determining centers of gravity of the determined contours, and filtering the outlier contours from the set of inspection contours based a relationship between a center of gravity and one or more vertices of a given contour.

In some embodiments, the filtering based on the relationship comprises filtering the given contour from the set of inspection contours responsive to the given contour having one or more vertices with distances from the center of gravity that breach a center of gravity distance threshold.

In some embodiments, the center of gravity distance threshold comprises a distance that is a given number of times, or a percentage, larger or smaller than an average distance between vertices and the center of gravity.

In some embodiments the method further comprises determining centers of gravity of the determined contours, fitting expected contour shapes to the determined contours based on the centers of gravity, and filtering the outlier contours from the set of inspection contours based a relationship between a fitted expected contour and vertices of a given contour.

In some embodiments, the method further comprises determining centers of gravity of the determined contours, fitting circles or ellipses to the determined contours based on the centers of gravity, and filtering the outlier contours from the set of inspection contours based a relationship between a fitted circle or ellipse and vertices of a given contour.

In some embodiments, the filtering based on the relationship comprises filtering the given contour from the set of inspection contours responsive to the given contour having one or more vertices with distances from the fitted circle or ellipse that breach a fitting distance threshold.

In some embodiments, the fitting distance threshold comprises a distance that is a given number of times, or a percentage, larger or smaller than an average distance between vertices and the fitted circle or ellipse.

In some embodiments, the contour comprises a polygon.

In some embodiments, the substrate pattern inspection images are generated with an optical inspection system or a charged particle inspection system. In some embodiments, the substrate pattern inspection images are generated with the charged particle inspection system, and the charged particle inspection system comprises a scanning electron microscope.

In some embodiments, the method further comprises determining a manufacturing variation of the features based on remaining contours in the set of inspection contours after the filtering. In some embodiments, the manufacturing variation is configured to be provided to a cost function to facilitate determination of costs associated with individual patterning process variables, and the costs associated with individual patterning process variables are configured to be used to facilitate optimization of a patterning process.

In some embodiments, determining contours in the substrate pattern inspection images to form the set of inspection contours comprises detecting repeating contours across a unit cell or a reticle associated with a pattern; and wherein filtering the outlier contours from the set of inspection contours comprises filtering each contour, or portion of a contour, associated with an outlier unit cell or outlier reticle.

According to another embodiment, there is provided a method for electronically filtering outlier contours from a set of inspection contours in substrate pattern inspection images. The method comprises receiving the substrate pattern inspection images. The method comprises determining contours based on the substrate pattern inspection images to form the set of inspection contours.

Determining contours comprises detecting edges of repeating features in the substrate pattern inspection images. The method comprises filtering the outlier contours from the set of inspection contours, leaving remaining contours in the set of inspection contours after the filtering.

In some embodiments, the method comprises determining a manufacturing variation of the repeating features based on remaining contours in the set of inspection contours after the filtering. The manufacturing variation is configured to be provided to a cost function to facilitate determination of costs associated with individual patterning process variables. The costs associated with individual patterning process variables are configured to be used to facilitate optimization of a patterning process.

In some embodiments, determining the manufacturing variation of the repeating features comprises stacking the remaining contours in the set of inspection contours, and statistically analyzing the stacked remaining contours.

In some embodiments, the filtering is performed based on individual points on the contours in the set of inspection contours, or geometrical shapes of the contours in the set of inspection contours. The filtering based on the individual points on the contours in the set of inspection contours comprises determining image contrasts or noise levels for pixel locations along a given contour in a substrate pattern inspection image. The filtering based on the geometrical shapes of the contours in the set of inspection contours comprises determining a smoothness of a geometrical shape of a given contour.

In some embodiments, determining contours based on the substrate pattern inspection images to form the set of inspection contours comprises detecting repeating contours across a unit cell or a reticle associated with a pattern. Filtering the outlier contours from the set of inspection contours comprises filtering each contour associated with an outlier unit cell or outlier reticle.

In some embodiments, the method comprises determining a score for each contour in the set of inspection contours and filtering the outlier contours from the set of inspection contours based on the score. In some embodiments, the score is determined based on individual points on the contours in the set of inspection contours, or geometrical shapes of the contours in the set of inspection contours, with reference to the substrate pattern inspection images. In some embodiments, the score comprises individual scores for each of multiple points on a contour, and the filtering is based on the individual scores. In some embodiments, the score comprises an overall score associated with a geometrical shape of a contour, and the filtering is based on the overall score.

In some embodiments, the substrate pattern inspection images are generated with an optical inspection system or a charged particle inspection system. In some embodiments, the substrate pattern inspection images are generated with the charged particle inspection system, and the charged particle inspection system comprises a scanning electron microscope.

According to another embodiment, there is provided a method for electronically filtering outlier contours from a set of inspection contours in substrate pattern inspection images. The method comprises receiving the substrate pattern inspection images and determining contours based on the substrate pattern inspection images to form the set of inspection contours. Determining contours comprises detecting edges of repeating features in the substrate pattern inspection images. The method comprises filtering the outlier contours from the set of inspection contours. The filtering is performed based on individual points on the contours in the set of inspection contours, or geometrical shapes of the contours in the set of inspection contours. The method comprises determining a manufacturing variation of the repeating features based on remaining contours in the set of inspection contours after the filtering.

In some embodiments, the manufacturing variation is configured to be provided to a cost function to facilitate determination of costs associated with individual patterning process variables. The costs associated with individual patterning process variables are configured to be used to facilitate optimization of a patterning process.

In some embodiments, determining the manufacturing variation of the repeating features comprises stacking the remaining contours in the set of inspection contours, and statistically analyzing the stacked remaining contours.

In some embodiments, filtering based on the individual points on the contours in the set of inspection contours comprises determining image contrasts or noise levels for pixel locations along a given contour in a substrate pattern inspection image. In some embodiments, filtering based on the geometrical shapes of the contours in the set of inspection contours comprises determining a smoothness of a geometrical shape of the given contour.

In some embodiments, determining contours based on the substrate pattern inspection images to form the set of inspection contours comprises detecting repeating contours across a unit cell or a reticle associated with a pattern. Filtering the outlier contours from the set of inspection contours comprises filtering each contour associated with an outlier unit cell or outlier reticle.

In some embodiments, the method comprises determining a score for each contour in the set of inspection contours and filtering the outlier contours from the set of inspection contours based on the score. The score is determined based on individual points on the contours in the set of inspection contours, or geometrical shapes of the contours in the set of inspection contours, with reference to the substrate pattern inspection images. In some embodiments, the score is indicative of a confidence level or a reliability.

In some embodiments, the score comprises individual scores for each of multiple points on a contour, and the filtering is based on the individual scores. In some embodiments, the score comprises an overall score associated with a geometrical shape of a contour, and the filtering is based on the overall score.

In some embodiments, the substrate pattern inspection images are generated with an optical inspection system. In some embodiments, the substrate pattern inspection images are generated with a charged particle inspection system. In some embodiments, the charged particle inspection system comprises a scanning electron microscope.

According to another embodiment, there is provided a non-transitory computer readable medium having instructions thereon, the instructions when executed by a computer, causing the computer to perform one or more of the method steps described above.

According to another embodiment, there is provided a system for electronically filtering outlier contours from a set of inspection contours in substrate pattern inspection images. The system comprises one or more hardware processors configured by machine readable instructions to perform one or more of the method steps described above.

According to another embodiment, there is provided a non-transitory computer readable medium having instructions thereon, the instructions when executed by a computer, causing the computer to electronically filter outlier contours from a set of inspection contours in substrate pattern inspection images. The filtering is configured to enhance a determination of manufacturing variation in, and optimization of, a patterning process compared to prior patterning processes. The instructions cause operations comprising: receiving the substrate pattern inspection images, where the substrate pattern inspection images are generated with a charged particle inspection system; determining contours based on the substrate pattern inspection images to form the set of inspection contours, where determining contours comprises detecting edges of repeating features in the substrate pattern inspection images; filtering the outlier contours from the set of inspection contours, where the filtering is performed based on individual points on the contours in the set of inspection contours, or geometrical shapes of the contours in the set of inspection contours; and determining a manufacturing variation of the repeating features based on remaining contours in the set of inspection contours after the filtering. The manufacturing variation is configured to be provided to a cost function to facilitate determination of costs associated with individual patterning process variables. The costs associated with individual patterning process variables are configured to be used to facilitate the optimization of the patterning process.

In some embodiments, filtering based on individual points on the contours in the set of inspection contours comprises determining characteristics of the substrate pattern inspection images including determining image contrasts or noise levels for pixel locations along the given contour in a substrate pattern inspection image; and filtering based on geometrical shapes of the contours in the set of inspection contours comprises determining a smoothness of a geometrical shape of the given contour.

In some embodiments, the operations further comprise determining a score for each contour in the set of inspection contours based on the individual points on the contours in the set of inspection contours, or the geometrical shapes of the contours in the set of inspection contours; and filtering the outlier contours from the set of inspection contours based on the score.

In some embodiments, determining the manufacturing variation of the repeating features comprises stacking the remaining contours in the set of inspection contours, and statistically analyzing the stacked remaining contours.

In some embodiments, the charged particle inspection system comprises a scanning electron microscope (SEM).

According to another embodiment, there is provided non-transitory computer readable medium having instructions thereon, the instructions when executed by a computer, causing the computer to electronically filter outlier contours from a set of inspection contours in substrate pattern inspection images. The filtering is configured to enhance a determination of manufacturing variation in, and optimization of, a patterning process compared to prior patterning processes. The instructions cause operations comprising: receiving the substrate pattern inspection images, where the substrate pattern inspection images are generated with a charged particle inspection system; determining contours in the substrate pattern inspection images to form the set of inspection contours, where determining contours comprises detecting edges of features in the substrate pattern inspection images, the edges comprising vertices of the contours; filtering the outlier contours from the set of inspection contours, where the filtering is performed based on the vertices; and determining a manufacturing variation of the features based on remaining contours in the set of inspection contours after the filtering, where the manufacturing variation is configured to be provided to a cost function to facilitate determination of costs associated with individual patterning process variables, and where the costs associated with individual patterning process variables are configured to be used to facilitate the optimization of the patterning process.

In some embodiments, the operations further comprise determining angles formed at the vertices of the determined contours, and filtering the outlier contours from the set of inspection contours based on the angles.

In some embodiments, the operations further comprise determining distances between adjacent vertices of the determined contours, and filtering the outlier contours from the set of inspection contours based on the distances.

In some embodiments, the operations further comprise determining centers of gravity of the determined contours, fitting circles, ellipses, or other expected contour shapes to the determined contours based on the centers of gravity, and filtering the outlier contours from the set of inspection contours based a relationship between a fitted circle ellipse, or other expected contour shape, and vertices of a given contour.

In some embodiments, the charged particle inspection system comprises a scanning electron microscope.

Other advantages of the embodiments of the present disclosure will become apparent from the following description taken in conjunction with the accompanying drawings, which set forth, by way of illustration and example, certain example embodiments.

### BRIEF DESCRIPTION OF THE DRAWINGS

The accompanying drawings, which are incorporated in and constitute a part of the specification, illustrate one or more embodiments and, together with the description, explain these embodiments. Embodiments will now be described, by way of example only, with reference to the accompanying schematic drawings in which corresponding reference symbols indicate corresponding parts, and in which:

FIG. 1 is a schematic diagram of a lithographic projection apparatus, according to an embodiment.

FIG. 2 depicts a schematic overview of a lithographic cell, according to an embodiment.

FIG. 3 depicts a schematic representation of holistic lithography, representing a cooperation between three technologies to optimize semiconductor manufacturing, according to an embodiment.

FIG. 4 schematically depicts an embodiment of a charged particle (e.g., an electron beam) inspection apparatus, according to an embodiment.

FIG. 5 schematically illustrates another embodiment of an inspection apparatus, according to an embodiment.

FIG. 6 illustrates a method for electronically filtering outlier contours from a set of inspection contours in substrate pattern inspection images, according to an embodiment.

FIG. 7 illustrates filtering based on the individual points on the contours in the set of inspection contours, according to an embodiment.

FIG. 8 illustrates filtering based on geometrical shapes of the contours in the set of inspection contours, according to an embodiment.

FIG. 9 illustrates a summary view of filtering based on an angle between vertices of a contour, filtering based on distances between vertices of a contour, filtering based on a distance between a center of gravity of a contour and one or more vertices on contour, and filtering based on a fit of an expected contour shape to a contour, according to an embodiment.

FIG. 10 illustrates determining angles formed at vertices of determined contours, and filtering outlier contours from a set of inspection contours based on the angles, according to an embodiment.

FIG. 11 illustrates determining distances between adjacent vertices of the determined contours, and filtering the outlier contours from the set of inspection contours based on the distances, according to an embodiment.

FIG. 12 illustrates determining centers of gravity of the determined contours, and filtering the outlier contours from the set of inspection contours based a relationship between a center of gravity and one or more vertices of a given contour, or an expected contour shape fitted to the given contour based on a center of gravity, according to an embodiment.

FIG. 13 illustrates an example of several filtered contours from a substrate pattern, according to an embodiment.

FIG. 14 illustrates a difference between a typical process (direct stacking, no filtering), and stacking and analysis after filtering, according to an embodiment.

FIG. 15 is a block diagram of an example computer system, according to an embodiment.

FIG. 16 is schematic diagram of another lithographic projection apparatus, according to an embodiment.

FIG. 17 is a more detailed view of components of a lithographic projection apparatus (e.g., the lithographic projection apparatus illustrated in FIG. 1 or FIG. 16), according to an embodiment.

FIG. 18 is a detailed view of the source collector module of a lithographic projection apparatus, according to an embodiment.

### DETAILED DESCRIPTION

Electronic devices are constructed of circuits formed on a piece of silicon called a substrate or a wafer. Many circuits may be formed as a repeating pattern of features together on the same piece of silicon, and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

To monitor manufacturing process variation, contours of identical pattern features may be determined based on SEM images of substrate patterns. The contours can be aggregated (e.g., stacked) and statistically analyzed to determine the variation of a given feature. Some of the contours are typically outliers, and the aggregation of the contours “hides” these outliers, which may result in reduced accuracy measurement/characterization of certain manufacturing process characteristics, such as critical dimension, edge placement error, or overlay error, among others. The present disclosure describes filtering certain outlier contours before they are aggregated and statistically analyzed. The filtering can be performed at multiple levels, such as based on individual points on the contours in a set of inspection contours, based on overall geometrical shapes of the contours in the set of inspection contours, based on angles between vertices of a contour, based on distances between vertices of a contour, based on a distance between a center of gravity of a contour and one or more vertices on the contour, based on a fit of an expected contour shape to a contour, or based on other information. This may enhance the accuracy of measurement/characterization of these manufacturing process characteristics, thereby enabling more optimal adjustments to be made to the manufacturing process to increase device yield, or may have other advantages.

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display (LCD) panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “projection optics,” as used herein, should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting, or projecting radiation from the source before the radiation passes the (e.g., semiconductor) patterning device, or optical components for shaping, adjusting, or projecting the radiation after the radiation passes the patterning device. The projection optics generally exclude the source and the patterning device.

A (e.g., semiconductor) patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include or specify specific parameters, limits on ranges for parameters, or other information. One or more of the design rule limitations or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. An example of a programmable LCD array is given in U.S. Pat. No. 5,229,872, which is incorporated herein by reference.

As used herein, the term “patterning process” generally means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer).

As used herein, a “printed pattern” means the physical pattern on a substrate that was etched based on a target pattern. The printed pattern can include, for example, troughs, channels, depressions, edges, or other two and three dimensional features resulting from a lithography process.

As used herein, the term “prediction model”, “process model”, “electronic model”, or “simulation model” (which may be used interchangeably) means a model that includes one or more models that simulate a patterning process. For example, a model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), an optical proximity correction (OPC) model (e.g., that can be used to make target patterns and may include sub-resolution resist features (SRAFs), etc.), an etch (or etch bias) model (e.g., that simulates the physical effects of an etching process on a printed wafer pattern), or other models.

As used herein, the term “calibrating” means to modify (e.g., improve or tune) or validate something, such as a model.

A patterning system may be a system comprising any or all of the components described above, plus other components configured to performing any or all of the operations associated with these components. A patterning system may include a lithographic projection apparatus, a scanner, systems configured to apply or remove resist, etching systems, or other systems, for example.

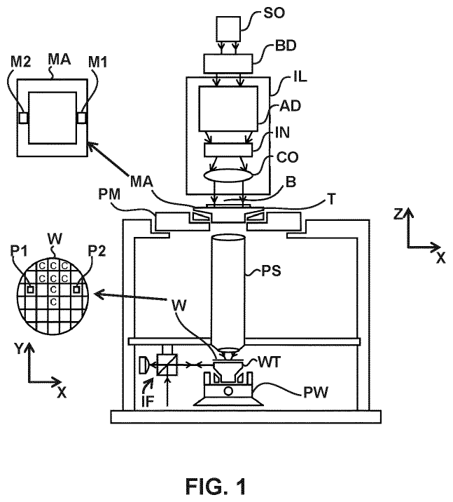

As an introduction, FIG. 1 is a schematic diagram of a lithographic projection apparatus, according to an embodiment. The lithographic projection apparatus can include an illumination system IL, a first object table T, a second object table WT, and a projection system PS. Illumination system IL, can condition a beam B of radiation. In this example, the illumination system also comprises a radiation source SO. First object table (e.g., a patterning device table) T can be provided with a patterning device holder to hold a patterning device MA (e.g., a reticle), and connected to a first positioner to accurately position the patterning device with respect to item PS. Second object table (e.g., a substrate table) WT can be provided with a substrate holder to hold a substrate W (e.g., a resist-coated silicon wafer), and connected to a second positioner to accurately position the substrate with respect to item PS. Projection system (e.g., which includes a lens) PS (e.g., a refractive, catoptric or catadioptric optical system) can image an irradiated portion of the patterning device MA onto a target portion C (e.g., comprising one or more dies) of the substrate W. Patterning device MA and substrate W may be aligned using patterning device alignment marks M1, M2 and substrate alignment marks P1, P2, for example.

As depicted, the apparatus can be of a transmissive type (i.e., has a transmissive patterning device). However, in general, it may also be of a reflective type, for example (with a reflective patterning device). The apparatus may employ a different kind of patterning device for a classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, or beam delivery system BD (comprising directing mirrors, the beam expander, etc.). for example. The illuminator IL may comprise adjusting means AD for setting the outer or inner radial extent (commonly referred to as a-outer and a-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus. The radiation beam that it produces may be led into the apparatus (e.g., with the aid of suitable directing mirrors), for example. This latter scenario can be the case when source SO is an excimer laser (e.g., based on KrF, ArF or F2 lasing), for example.

The beam B can subsequently intercept patterning device MA, which is held on a patterning device table T. Having traversed patterning device MA, the beam B can pass through the lens PL, which focuses beam B onto target portion C of substrate W. With the aid of the second positioning means (and interferometric measuring means IF), the substrate table WT can be moved accurately, e.g. to position different target portions C in the path of beam B. Similarly, the first positioning means can be used to accurately position patterning device MA with respect to the path of beam B, e.g., after mechanical retrieval of the patterning device MA from a patterning device library, or during a scan. In general, movement of the tables T, WT can be realized with the aid of a long-stroke module (coarse positioning) and a short-stroke module (fine positioning). However, in the case of a stepper (as opposed to a step-and-scan tool), patterning device table T may be connected to a short stroke actuator, or may be fixed.

The depicted tool can be used in two different modes, step mode and scan mode. In step mode, patterning device table T is kept essentially stationary, and an entire patterning device image is projected in one operation (i.e., a single “flash”) onto a target portion C. Substrate table WT can be shifted in the x or y directions so that a different target portion C can be irradiated by beam B. In scan mode, essentially the same scenario applies, except that a given target portion C is not exposed in a single “flash.” Instead, patterning device table T is movable in a given direction (e.g., the “scan direction”, or the “y” direction) with a speed v, so that projection beam B is caused to scan over a patterning device image. Concurrently, substrate table WT is simultaneously moved in the same or opposite direction at a speed V=Mv, in which M is the magnification of the lens (typically, M=¼ or ⅕). In this manner, a relatively large target portion C can be exposed, without having to compromise on resolution.

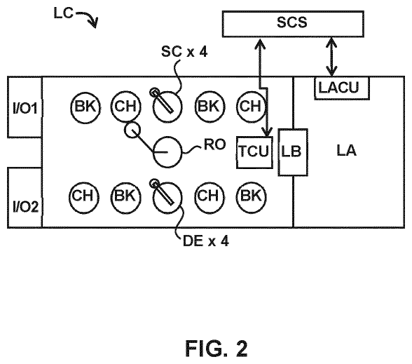

FIG. 2 depicts a schematic overview of a lithographic cell LC. As shown in FIG. 2 the lithographic apparatus LA may form part of lithographic cell LC, also sometimes referred to as a lithocell or (litho)cluster, which often also includes apparatus to perform pre- and post-exposure processes on a substrate W. Conventionally, these include spin coaters SC configured to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W (FIG. 1) exposed by the lithographic apparatus LA to be exposed correctly and consistently, it is desirable to inspect substrates to measure properties of patterned structures, such as feature edge placement, overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W (FIG. 1), and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties using an actual substrate (e.g., a charged particle—SEM—image of a wafer pattern) or an image of an actual substrate, on a latent image (image in a resist layer after the exposure), on a semi-latent image (image in a resist layer after a post-exposure bake step PEB), on a developed resist image (in which the exposed or unexposed parts of the resist have been removed), on an etched image (after a pattern transfer step such as etching), or in other ways.

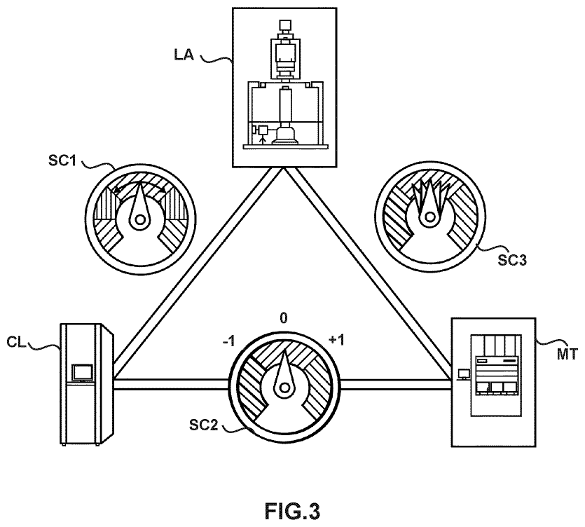

FIG. 3 depicts a schematic representation of holistic lithography, representing a cooperation between three technologies to optimize semiconductor manufacturing. Typically, the patterning process in a lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is the lithographic apparatus LA which is (virtually) connected to a metrology apparatus (e.g., a metrology tool) MT (a second system), and to a computer system CL (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) a design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology apparatus (tool) MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequent measurements of the structures created, e.g., for process control and verification. Tools to make such measurements include metrology tool (apparatus) MT. Different types of metrology tools MT for making such measurements are known, including scanning electron microscopes (SEM) or various forms of scatterometer metrology tools MT. In some embodiments, metrology tools MT are or include an SEM.

In some embodiments, metrology tools MT are or include a spectroscopic scatterometer, an ellipsometric scatterometer, or other light based tools. A spectroscopic scatterometer may be configured such that the radiation emitted by a radiation source is directed onto target features of a substrate and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra. An ellipsometric scatterometer allows for determining parameters of a lithographic process by measuring scattered radiation for each polarization states. Such a metrology tool (MT) emits polarized light (such as linear, circular, or elliptic) by using, for example, appropriate polarization filters in the illumination section of the metrology apparatus. A source suitable for the metrology apparatus may provide polarized radiation as well.

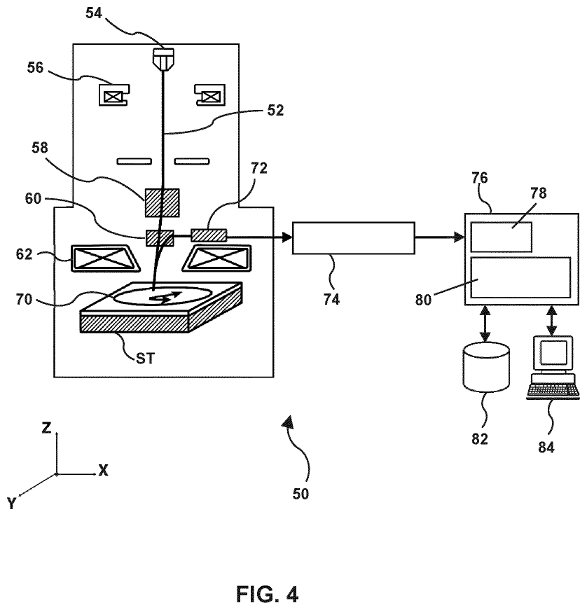

As described above, fabricated devices (e.g., patterned substrates) may be inspected at various points during manufacturing. FIG. 4 schematically depicts a generalized embodiment of an charged particle (electron beam) inspection apparatus 50. In some embodiments, inspection apparatus 50 may be an electron beam or other charged particle inspection apparatus (e.g., the same as or similar to a scanning electron microscope (SEM)) that yields an image of a structure (e.g., some or all the structure of a device, such as an integrated circuit) exposed or transferred on a substrate. A primary electron beam 52 emitted from an electron source 54 is converged by condenser lens 56 and then passes through a beam deflector 58, an E x B deflector 60, and an objective lens 62 to irradiate a substrate 70 on a substrate table ST at a focus.

When the substrate 70 is irradiated with electron beam 52, secondary electrons are generated from the substrate 70. The secondary electrons are deflected by the E x B deflector 60 and detected by a secondary electron detector 72. A two-dimensional electron beam image can be obtained by detecting the electrons generated from the sample in synchronization with, e.g., two dimensional scanning of the electron beam by beam deflector 58 or with repetitive scanning of electron beam 52 by beam deflector 58 in an X or Y direction, together with continuous movement of the substrate 70 by the substrate table ST in the other of the X or Y direction. Thus, in some embodiments, the electron beam inspection apparatus has a field of view for the electron beam defined by the angular range into which the electron beam can be provided by the electron beam inspection apparatus (e.g., the angular range through which the deflector 60 can provide the electron beam 52). Thus, the spatial extent of the field of the view is the spatial extent to which the angular range of the electron beam can impinge on a surface (wherein the surface can be stationary or can move with respect to the field).

As shown in FIG. 4, a signal detected by secondary electron detector 72 may be converted to a digital signal by an analog/digital (A/D) converter 74, and the digital signal may be sent to an image processing system 76. In some embodiments, the image processing system 76 may have memory 78 to store all or part of digital images for processing by a processing unit 80. The processing unit 80 (e.g., specially designed hardware or a combination of hardware and software or a computer readable medium comprising software) is configured to convert or process the digital images into datasets representative of the digital images. In some embodiments, the processing unit 80 is configured or programmed to cause execution of an operation (e.g., SEM inspection) described herein. Further, image processing system 76 may have a storage medium 82 configured to store the digital images and corresponding datasets in a reference database. A display device 84 may be connected with the image processing system 76, so that an operator can conduct necessary operation of the equipment with the help of a graphical user interface.

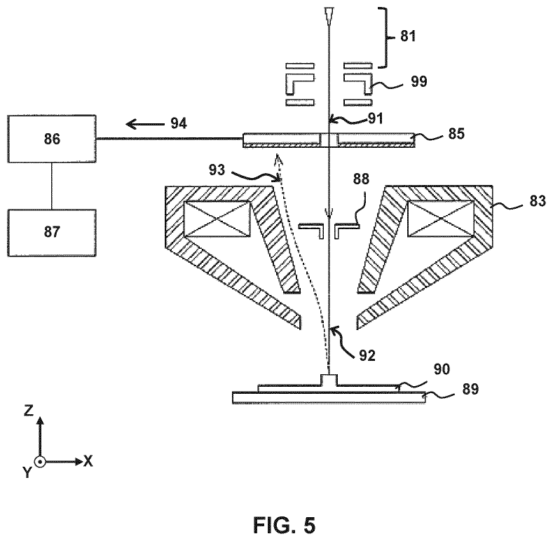

FIG. 5 schematically illustrates another embodiment of a charged particle inspection apparatus. The apparatus is used to inspect a sample 90 (such as a patterned substrate) on a sample stage 89 and comprises a charged particle beam generator 81, a condenser lens module 99, a probe forming objective lens module 83, a charged particle beam deflection module 88, a secondary charged particle detector module 85, an image forming module 86, or other components. The charged particle beam generator 81 generates a primary charged particle beam 91. The condenser lens module 99 condenses the generated primary charged particle beam 91. The probe forming objective lens module 83 focuses the condensed primary charged particle beam into a charged particle beam probe 92. The charged particle beam deflection module 88 scans the formed charged particle beam probe 92 across the surface of an area of interest on the sample 90 secured on the sample stage 89. In some embodiments, the charged particle beam generator 81, the condenser lens module 83, and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly form at least one scanned image. In some embodiments, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In some embodiments, a monitoring module 87 is coupled to the image forming module 86 of the image forming apparatus to monitor, control, etc. the patterning process or derive a parameter for patterning process design, control, monitoring, etc. using the scanned image of the sample 90 received from image forming module 86. In some embodiments, the monitoring module 87 is configured or programmed to cause execution of an operation described herein. In some embodiments, the monitoring module 87 comprises a computing device. In some embodiments, the monitoring module 87 comprises a computer program configured to provide functionality described herein. In some embodiments, a probe spot size of the electron beam in the system of FIG. 3 is significantly larger compared to, e.g., a CD, such that the probe spot is large enough so that the inspection speed can be fast. However, the resolution may be lower because of the large probe spot.

As described above, it may be desirable to use one or more tools to produce results that, for example, can be used to design, control, monitor, etc. a patterning process. One or more tools used in computationally controlling, designing, etc. one or more aspects of the patterning process, such as the pattern design for a patterning device (including, for example, adding sub-resolution assist features or optical proximity corrections), the illumination for the patterning device, etc., may be provided. Accordingly, in a system for computationally controlling, designing, etc. a manufacturing process involving patterning, the manufacturing system components or processes can be described by various functional modules or models. In some embodiments, one or more electronic (e.g., mathematical, parameterized, etc.) models may be provided that describe one or more steps or apparatuses of the patterning process. In some embodiments, a simulation of the patterning process can be performed using one or more electronic models to simulate how the patterning process forms a patterned substrate using a design pattern provided by a patterning device.

Images, from, e.g., the system of FIG. 4 or FIG. 5, may be processed to extract dimensions, shapes, contours, or other information that describe the edges of objects, representing semiconductor device structures, in the image. The shapes, contours, or other information may be quantified via metrics, such as edge placement error (EPE), CD, etc. at user-defined cut-lines or in other locations. These shapes, contours, or other information may be used to optimize a patterning process, for example.

In some embodiments, optimization of a patterning process may be represented as a cost function. The optimization process may comprise finding a set of parameters (design variables, process variables, etc.) of the patterning process that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design or process variables of the patterning process can be confined to finite ranges or be interdependent due to practicalities of implementations of the system or method. In the case of a lithographic projection apparatus, the constraints are often associated with physical properties and characteristics of the hardware such as tunable ranges, or patterning device manufacturability design rules. The evaluation points can include physical points in an image of a substrate, as well as non-physical characteristics such as one or more etching parameters, dose and focus, etc., for example.

In an etching system, as an example, a cost function (CF) may be expressed as

$$C F ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} )$$

where (z₁, z₂, . . . , z_{N}) are N design variables or values thereof, and fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). In some embodiments, wₚ is a weight constant associated with fₚ(z₁, z₂, . . . , z_{N}). For example, the characteristic may be a position of an edge of a pattern (e.g., or multiple points on an edge that form a contour), measured at a given point on the edge. Different f,(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in the equation above and CF(z₁, z₂, . . . , z_{N}) can be in any other suitable form.

The cost function may represent any one or more suitable characteristics of a patterning system, a patterning process, lithographic apparatus, lithography process, or the substrate, for instance, focus, CD, image shift, image distortion, image rotation, stochastic variation, throughput, local CD variation, process window, an interlayer characteristic, or a combination thereof. In some embodiments, the cost function may include a function that represents one or more characteristics of a resist image. For example, fₚ(z₁, Z₂, . . . , z_{N}) can be simply a distance between a point in the resist image to an intended position of that point (i.e., edge placement error EPEₚ(z₁, z₂, . . . , z_{N}) after etching, for example, or some other process. The parameters (e.g., design variables) can include any adjustable parameter such as an adjustable parameter of the etching system, the source, the patterning device, the projection optics, dose, focus, etc.

The parameters (e.g., design variables) may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. Constraints should not be interpreted as a necessity.

Contours of pattern features are often determined based on images of substrate patterns. These contours are used to determine various key performance indicators (KPI), which are in turn used to monitor semiconductor manufacturing process variation. As one example, edge placement error (EPE) has become a common KPI used for monitoring process variation. EPE includes contributions from imaging (e.g., critical dimension (CD) and pattern placement variations) and overlay.

Contours are stacked and analyzed (e.g., EPE or other KPI's are determined) to determine the variation in a given feature. However, some of the contours may be outliers, and the stacking and averaging of the contours “hides” these outliers. For example, the contours may have varying quality (e.g., images may not provide clean, clear, views of edges of features used to determine the contours, and instead may be pixelated, blurry, etc.) or confidence levels (e.g., it may be unclear from a lower quality image exactly where a contour lies in that image, or a particular manufacturing process may have produced an unusual result). Outliers may be caused, for example, by process variation or tool condition drift, because of the intrinsic differences of a pattern design (some patterns are more challenging for imaging, analysis, or other extraction tasks), or for other reasons. If these outlier contours go into a stack and an analysis is performed based on them, the outlier contours may impact any determinations drawn from that stack. Using EPE as an example, an EPE calculation based on a stack that includes outlier contours may cause errant (or at least less accurate) EPE determinations, and unnecessary manufacturing process adjustments to certain manufacturing parameters, when the “budget” for such adjustments may have been best used on other manufacturing parameters.

Advantageously, the present disclosure describes filtering certain outlier contours before they are aggregated (e.g., stacked) and statistically analyzed. Each contour is analyzed and, in some embodiments, a score rates how close to “ideal” the contour is, and the contours with scores below a threshold are filtered and the remaining contours are aggregated. The filtering can be performed at multiple levels, such as based on individual points on the contours in a set of inspection contours, based on overall geometrical shapes of the contours in the set of inspection contours, based on angles between vertices of a contour, based on distances between vertices of a contour, based on a distance between a center of gravity of a contour and one or more vertices on the contour, based on a fit of an expected contour shape to a contour, at a unit cell level (which includes a plurality of different contours of different features), or at a die or reticle level.

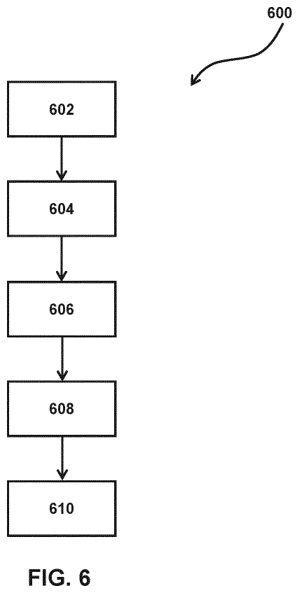

FIG. 6 illustrates an exemplary method 600 for electronically filtering outlier contours from a set of inspection contours in substrate pattern inspection images. The filtering is configured to enhance a determination of manufacturing variation in, and optimization of, a patterning process compared to prior patterning processes. Method 600 comprises receiving (operation 602) the substrate pattern inspection images, determining (operation 604) contours based on the substrate pattern inspection images to form the set of inspection contours, filtering (operation 606) the outlier contours from the set of inspection contours, determining (operation 608) a manufacturing variation of the repeating features, and providing (operation 610) the manufacturing variation to a cost function to facilitate determination of costs associated with individual patterning process variables, or in other operations.

In some embodiments, a non-transitory computer readable medium stores instructions which, when executed by a computer, cause the computer to execute one or more of operations 602-610, or other operations. The operations of method 600 are intended to be illustrative. In some embodiments, method 600 may be accomplished with one or more additional operations not described, or without one or more of the operations discussed. For example, operation 610 or other operations may be optional. Additionally, the order in which the operations of method 600 are illustrated in FIG. 6 and described herein is not intended to be limiting.

At operation 602, the substrate pattern inspection images are received. The substrate pattern inspection images are generated with an optical inspection system, a charged particle inspection system, an electronic model, or other systems. The optical inspection system may be a scatterometer (as described above), for example, or other optical inspection systems. The charged particle inspection system can be or include a scanning electron microscope (e.g., as shown in FIGS. 4 and 5 and described above), for example, or other charged particle inspection systems such as a multi-beam charged particle inspection system. The electronic model may be any electronic model that generates a representation of a substrate pattern.

The substrate pattern inspection images may include information describing the geometrical shapes of contours in a pattern or information related to the geometrical shapes. The geometrical shapes of the contours in the pattern may be two dimensional geometrical shapes, for example. The received substrate pattern inspection images include data that describes the characteristics of the contours (e.g., such as X-Y dimensional data points, a mathematical equation that describes a geometrical shape, etc.), processing parameters associated with the contour, or other data. The images may further include 3D information, such as information about features that are buried in one or more sub-layers, data from prior inspections of prior layers, information selected and input by a user operating inspection system that generates the inspection images, or other information.

The substrate pattern inspection images may be received electronically from one or more other portions of the present system (e.g., from a different processor, or from a different portion of a single processor), from a remote computing system not associated with a present system, from an (optical or charged particle) inspection system, or from other sources. The substrate pattern inspection images may be received wirelessly or via wires, via a portable storage medium, or from other sources. The substrate pattern inspection images may be uploaded or downloaded from another source, such as cloud storage for example, or received in other ways.

At operation 604, contours are determined based on the substrate pattern inspection images. Determining contours comprises detecting edges of features in the substrate pattern inspection images. The features can be repeating or non-repeating. In some embodiments, a contour comprises a set of points indicating the boundary or edge location surrounding a pattern feature in an image (e.g., an SEM image). Detecting the edges of these features may comprise detecting these points using localized (e.g., pixels or other localized indicators) image characteristics, an electronic file (e.g., a .GDS file) or other source that specifies the locations of edges or other dimensional information for a pattern, or other information. The image characteristics may include contrast, sharpness, color, noise, or other characteristics or information. By way of a non-limiting example, an edge of a feature may be detected based on strong contrasts between similar or dissimilar colors in several adjacent pixels in a given image (e.g., which would indicate a sharp edge). As another non-limiting example, using SEM images, localized contour point detections may result in several candidate edge points being identified near one location on a pattern feature, in which case the sharpest point may be selected as the most likely edge point (i.e., one single sharp edge is easier to locate with less uncertainty than several sharp edges in the same window). The likelihood may be generated based on a local probability model, and may be quantified as a KPI, for example.

In some embodiments, operation 604 includes detecting contours for identical repeating features across a unit cell or a reticle (e.g., a patterning device as described above) associated with a pattern, for example. The determined contours for the identical repeating features can form a set of inspection contours.

At operation 606, the outlier contours are filtered from the set of inspection contours, leaving remaining contours in the set of inspection contours after the filtering. The filtering is performed based on individual points on the contours in the set of inspection contours, geometrical shapes of the contours in the set of inspection contours, based on angles between vertices of a contour, based on distances between vertices of a contour, based on a distance between a center of gravity of a contour and one or more vertices on the contour, based on a fit of an expected contour shape to a contour, or other information. In some embodiments, filtering the outlier contours from the set of inspection contours comprises filtering each contour associated with an outlier unit cell or an outlier reticle, for example.

By way of a non-limiting example, a point based KPI (e.g., EPE) can be determined for a contour detected based on local gray level contrast information in an image. A sharp edge with strong contrast in the image is easy to locate, with less uncertainty than a blurry edge. Each point in a contour can be associated with a KPI value, which provides point-level confidence information. Points located along a sharp edge in such an image comprise a contour configured to be kept in a set of inspection contours (e.g., such that any KPI values determined for points along this contour are used in future calculations), while points located along a blurry edge comprise a contour configured to be filtered (e.g., such that any KPI values determined for points along this contour are filtered and not used in future calculations).

As another non-limiting example, a feature (polygon) level KPI can be determined using the geometrical shape of a contour. In this example, if the detected edge of a feature forms a contour with sharp spikes or multiple disconnected regions (or other unusual or unexpected overall shapes of a feature), as two possible examples, the contour may be filtered from a set of inspection contours (e.g., such that any feature level KPI values determined using this contour are filtered and not used in future calculations). These concepts may be extended to include unit cell level filtering, die or reticle level filtering, or other filtering. In addition, these concepts may be extended to include a soft filtering/kernel density estimate for percentile contours with a KPI, for example.

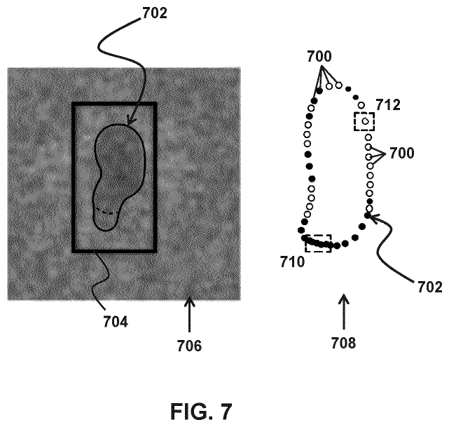

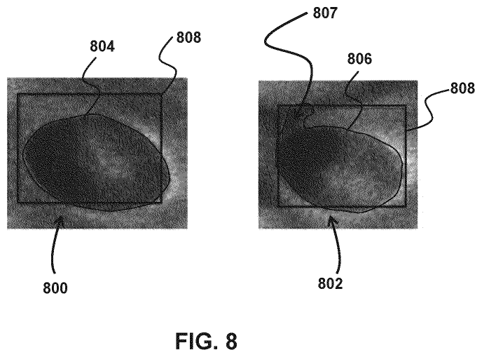

FIG. 7 and FIG. 8 illustrate additional detail related to point based filtering (FIG. 7) and geometrical shape based filtering (FIG. 8). FIG. 7 illustrates filtering based on the individual points 700 on a contour 702 in a set of inspection contours for repeating features 704. In some embodiments, this comprises determining image contrasts, colors, sharpness, or noise levels for pixel locations at points 700 along contour 702 in a substrate pattern inspection image 706. FIG. 7 illustrates a heat map 708 of points 700 on contour 702. In heat map 708, darker shades indicate a lower confidence level (e.g., determined based on the image contrasts, colors, sharpness, noise, etc.) that contour 702 actually lies at a given point 700, and lighter shades indicate a higher confidence level. Heat map 708 indicates portions of contour 702 associated with lower confidence 710 and higher confidence 712. In practice, using the present systems and methods, portions of contour 702 associated with lower confidence 710 would be filtered from a set of inspection contours, while portions of contour 702 associated with higher confidence 712 would remain in the set of inspection contours.

FIG. 8 illustrates filtering based on geometrical shapes 800, 802 of the contours 804, 806 in a set of inspection contours for a (repeating) feature 808. FIG. 8 shows examples of contours 804, 806 of two individual contact holes (repeating feature 808). In some embodiments, the filtering based on geometrical shapes 800, 802 of contours 804, 806 in the set of inspection contours comprises determining a smoothness of geometrical shape 800, 802 of a given contour 804, 806. Here, for example, contour 804 has a relatively smooth geometrical shape, while contour 806 has a shape deviation 807. Contour 806 is impacted by a shadow, which appears to cause deviation 807. A geometry-based KPI would likely have different values for contours 804 and 806. In practice, using the present systems and methods to enhance the accuracy of a geometry based KPI determined from a set of inspection contours for feature 808 (or for other reasons), contour 806 would be filtered from the set of inspection contours, while contour 804 would remain in the set of inspection contours.

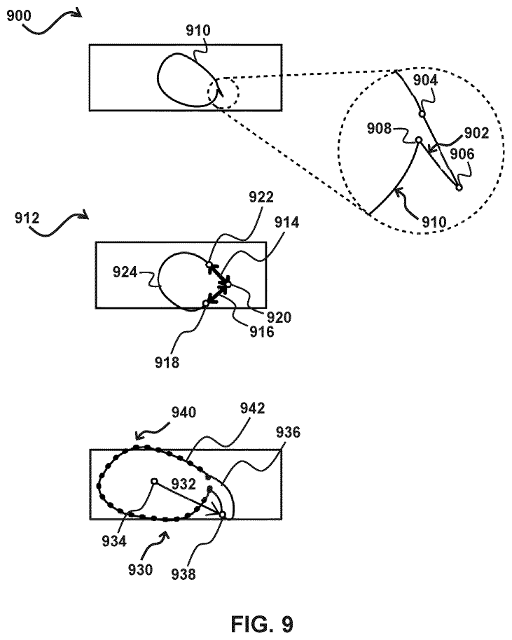

FIG. 9 illustrates a summary view of filtering 900 based on an angle 902 between vertices 904, 906, 908 of a contour 910, filtering 912 based on distances 914, 916 between vertices (918 and 920 and 920 and 922) of a contour 924, filtering 930 based on a distance 932 between a center of gravity 934 of a contour 936 and one or more vertices 938 on contour 936, and filtering 940 based on a fit of an expected contour shape 942 to contour 936. In some embodiments, a pattern feature comprises a polygon. In other words, a pattern feature may be multi-sided or multi-edged. A contour comprises a side or an edge (or portion of a side or edge) of a polygon. A contour may be or include a multi-segment line, curve, or other shape, for example. The multi-segment line, curve, etc., may have joints between segments. Vertices of the contour may be located at the joints or other intersection points of the segments of the line or curve. Filtering outlier contours may be based at least in part on these vertices, as described below.

Referring to FIG. 9 and filtering 900, angles (e.g., angle 902) for adjacent segments at each vertex 904, 906, 908 may be determined, and if an angle breaches a given threshold (e.g., 90 degrees), contour 910 may cause the corresponding feature (or at least that local portion of the feature) to be filtered. Referring to filtering 912, distances 914 and 916 between adjacent vertices 918, 920, 922 (or other points on contour 924) may be determined, and if a distance breaches a given threshold (e.g., a specific distance or process parameter requirement such as edge roughness as one example), contour 924 may cause the corresponding feature (or at least that local portion of the feature) to be filtered. Referring to filtering 930 and 940, center of gravity 934 may be determined, and then an expected feature shape (e.g., a circle or ellipse) may be fitted to the contour and the fit may be checked for outlier vertices (e.g., by checking distances from center of gravity 934 to locations on contour 936, checking a difference between an expected fit and an actual fit, etc.) or other points on contour 936. Each of these examples are discussed in more detail below.

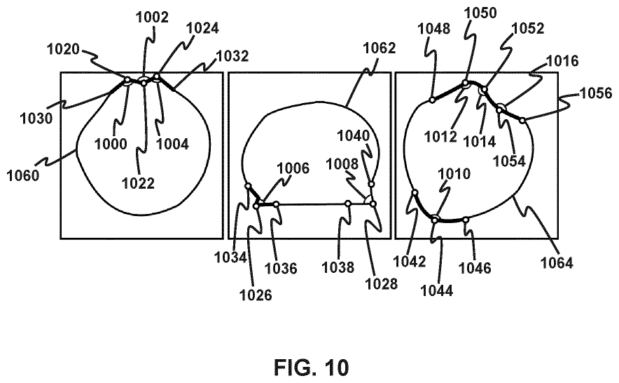

FIG. 10 illustrates determining angles 1000-1016 formed at vertices 1020-1056 of determined contours 1060, 1062, and 1064, and filtering outlier contours 1060, 1062, from the set of inspection contours (formed by contours 1060, 1062, and 1064 as a group) based on angles 1000-1016. Contour 1064 is retained in this example. Filtering outlier contours 1060, 1062 from the set of inspection contours is based on comparisons of the determined angles 1000-1016 to an angle threshold. The threshold may be determined by a user via entries or selections made via a user interface (e.g., as described below), determined automatically by a processor (as described herein) based on (current or historical) dimensional data or other information, or may be determined in other ways. For example, a user, based on experience, process data, etc., may set a threshold to ensure the filtering process does not over or under filter contours based on these angles. Determined contours with an angle at a vertex that breaches the angle threshold are determined to be outlier contours and filtered from the set of inspection contours. For example, determined contours with an angle at a vertex smaller than the angle threshold are determined to be outlier contours and filtered from the set of inspection contours. Such a threshold angle may be 120, 90, 60, or 45 degrees, or other angles. As another example, determined contours with an angle at a vertex larger than the angle threshold are determined to be outlier contours and filtered from the set of inspection contours. Such a threshold angle may be 150, 160, 170, or 180 degrees, or other angles. Note that, as described herein, in some embodiments, only those portions of a contour whose angles breach the threshold angle may be filtered, while the rest of the contour is retained, or the whole contour may be filtered.

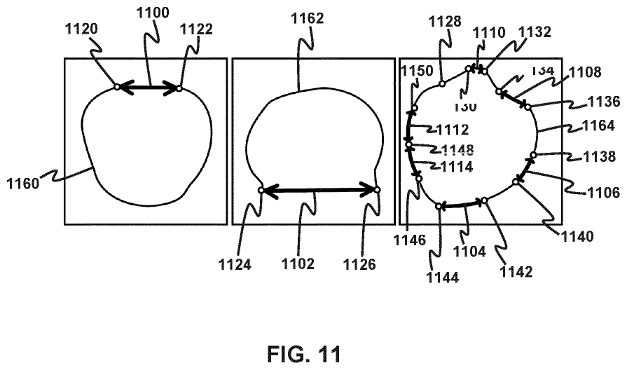

FIG. 11 illustrates determining distances 1100-1114 between adjacent vertices 1120-1150 of the determined contours 1160, 1162, 1164, and filtering outlier contours 1160 and 1162 from the set of inspection contours (formed by contours 1160, 1162, and 1164 as a group) based on distances 1100-1114. In some embodiments, filtering outlier contours 1160 and 1162 from the set of inspection contours is based on comparisons of the determined distances 1100-1114 to a distance threshold. Determined contours with a distance that breaches the distance threshold are determined to be outlier contours and filtered from the set of inspection contours. In some embodiments, the distance threshold comprises a specific value, a distance that is a given number of times (e.g., 2×, 5×, 10×, etc.), or a percentage (e.g., 150%, 200%, etc.), larger or smaller than an average distance between vertices; or a distance that corresponds to a contour edge roughness parameter, or other process parameters, for example. In some embodiments the type or magnitude of the threshold may be determined by a user via entries or selections made via a user interface (e.g., as described below), determined automatically by a processor (as described herein) based on (current or historical) dimensional data or other information, or may be determined in other ways. For example, a user, based on experience, process data, etc., may set a threshold to ensure the filtering process does not over or under filter contours based on these distances. Note that, as described herein, in some embodiments, only those portions of a contour whose distances breach the threshold distance may be filtered, while the rest of the contour is retained, or the whole contour may be filtered.

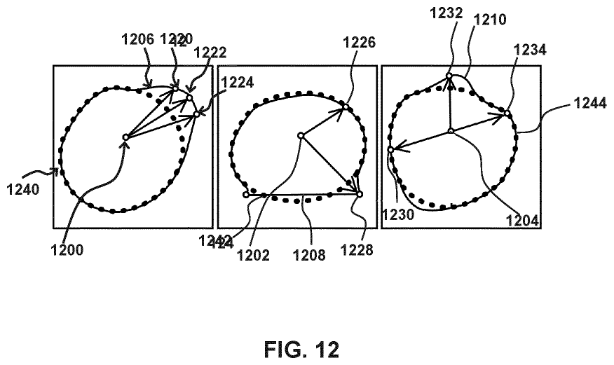

FIG. 12 illustrates determining centers of gravity 1200, 1202, 1204 of the determined contours 1206, 1208, 1210, and filtering outlier contours 1206 and 1208 from the set of inspection contours (formed by contours 1206, 1208, and 1210 as a group) based a relationship between a center of gravity 1200, 1202, 1204, and one or more vertices 1220-1234 of a given contour, or an expected contour shape 1240, 1242, 1244 fitted to the given contour based on a center of gravity 1200, 1202, or 1204. In some embodiments, filtering based on the relationship comprises filtering a given contour (e.g., contour 1206 or 1208) from the set of inspection contours responsive to the given contour having one or more vertices (e.g., vertices 1220, 1222, 1224, 1228) with distances from the center of gravity (e.g., 1200 or 1202) that breach a center of gravity distance threshold. The center of gravity distance threshold comprises a distance that is a given number of times, or a percentage, larger or smaller than an average distance between vertices and the center of gravity, for example, or other distances.

In some embodiments, the filtering comprises determining the centers of gravity 1200, 1202, 1204 of the determined contours 1206, 1208, 1210, fitting expected contour shapes 1240, 1242, 1244 to the determined contours 1206, 1208, 1210, based on the centers of gravity 1200, 1202, 1204, and filtering the outlier contours 1206, 1208 from the set of inspection contours based a relationship between a fitted expected contour shape 1240, 1242 (in this example) and vertices of a given contour (e.g., 1220, 1222, 1224 for expected contour shape 1240, and 1228 for expected contour shape 1242 in this example). In some embodiments, the expected contour shape comprises a circle, an ellipse, or other shapes, for example. In some embodiments, filtering based on the relationship comprises filtering the given contour from the set of inspection contours responsive to the given contour having one or more vertices with distances from the fitted circle or ellipse that breach a fitting distance threshold. In other words, a contour may be filtered if vertices of the contour do not lie on or near the fitted expected contour shape. In some embodiments, the fitting distance threshold comprises a distance that is a given number of times, or a percentage, larger or smaller than an average distance between vertices and the fitted circle or ellipse.

Similar to the other thresholds described above, the center of gravity distance threshold and the fitting distance threshold may be determined by a user via entries or selections made via a user interface (e.g., as described below), determined automatically by a processor (as described herein) based on (current or historical) dimensional data or other information, or may be determined in other ways. For example, a user, based on experience, process data, etc., may set a threshold to ensure the filtering process does not over or under filter contours based on these distances. Note that, as described herein, in some embodiments, only those portions of a contour whose distances breach the threshold distance may be filtered, while the rest of the contour is retained, or the whole contour may be filtered.

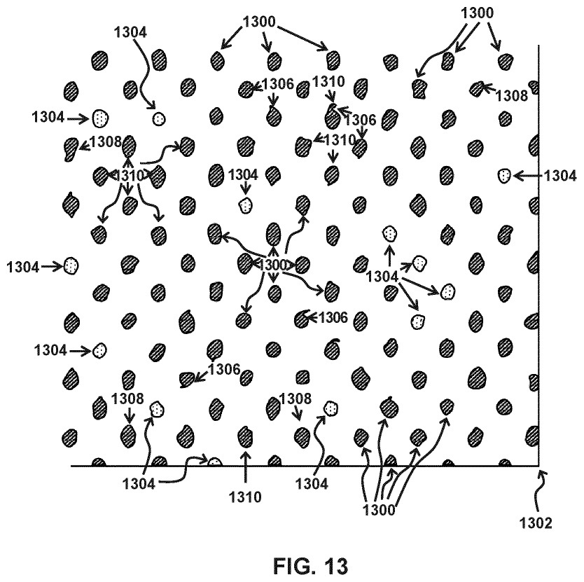

FIG. 13 an example of several filtered contours 1300 from a substrate pattern 1302. FIG. 13 also illustrates several unfiltered (acceptable) contours 1304. Contours 1300 are filtered (or not filtered) based on one or more of the operations described above. For example, as shown in FIG. 13, some contours 1306 are filtered based on angles between vertices, some contours 1308 are filtered based on distances between vertices, some contours 1310 are filtered based on their center of gravity and a fitted expected contour, and some contours are filtered based on a combination of two or more of these factors.

Returning to FIG. 6, in some embodiments, operation 606 comprises determining a score for each contour in the set of inspection contours and filtering the outlier contours from the set of inspection contours based on the score. The score may be determined based on individual points on the contours in the set of inspection contours, geometrical shapes of the contours in the set of inspection contours, or other information. In some embodiments, the score comprises individual scores for each of multiple points on a contour, and the filtering is based on the individual scores. In some embodiments, the score comprises an overall score associated with a geometrical shape of a contour, and the filtering is based on the overall score.

In some embodiments, each contour in a set of inspection contours is analyzed (e.g., as described in one or more of the examples above) and assigned a score. In some embodiments, the score rates a confidence in the reliability of the location of a detected contour (e.g., as described above), or in various KPI's calculated for a contour at specific locations on a contour. For example, the score may be a statistical confidence value. The statistical confidence value may be for a specific KPI (such as EPE or CD as two examples) at a specific point-level location (though this can also be applied at a feature geometrical shape level, a unit cell level, or a die or reticle level).

In some embodiments, the score rates the contour's proximity to an “ideal” contour. The ideal contour may be, or may be determined based on, a target feature design, an expected shape of a feature given prior manufacturing processing steps, or other information. The ideal contour may be specified by a user (e.g., by uploading or downloading an electronic file, designating a specific contour as “ideal”, specifying dimensions or locations where a contour or points along a contour should lie, etc.), generated by an electronic model, determined from manufacturing process measurements, determined based on a resemblance to a substrate pattern image, or obtained in other ways. Proximity to an ideal contour may refer to a difference between a measurement taken at a particular location associated with a contour and an expected or allowable range for that measurement (e.g., proximity can also be decided based on a (known or unknown) relationship between a contour and a substrate pattern image), an amount a given contour deviates from an expected or allowable geometrical shape, or other measures of proximity.

In some embodiments, the contours with scores that breach (e.g., lie above or below depending on how the present system or method is configured) a threshold are filtered and the remaining contours are aggregated (e.g., stacked). A threshold may be determined based on a target feature design, an expected shape of a feature given prior manufacturing processing steps, or other information. A threshold may be specified by a user (e.g., by uploading or downloading an electronic file; entering a specific threshold using a user interface (described below); specifying dimensions or locations associated with a threshold, etc.); generated by an electronic model; determined from manufacturing process measurements; determined based on SEM image related metrics or user inputs such as gradient sensitivity, peak spread tolerance, etc.; or determined in other ways.

At operation 608 a manufacturing variation of the repeating features is determined. The manufacturing variation of the repeating features may be determined based on remaining contours in a set of inspection contours after filtering. In some embodiments, determining the manufacturing variation of the repeating features comprises stacking the remaining contours in the set of inspection contours, and statistically analyzing the stacked remaining contours.

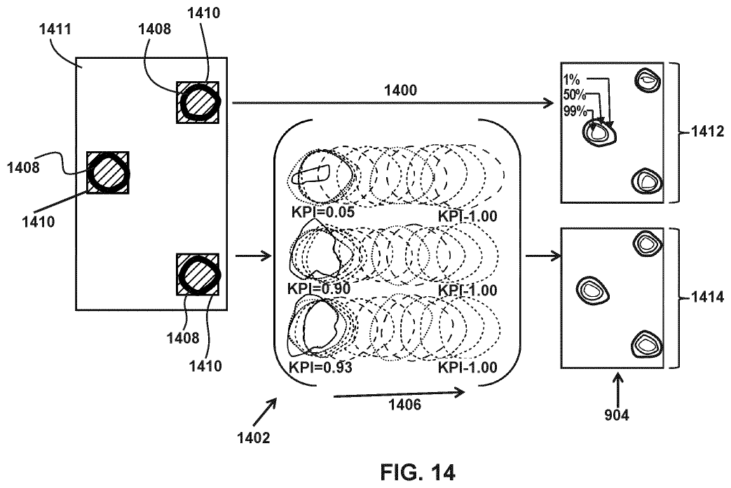

FIG. 14 illustrates a difference between a typical process 1400 (see the arrow indicating direct stacking, no filtering—e.g., the arrow advances directly from contours 1408 to analysis 1404 described below), and stacking 1402 and analysis 1404 with filtering 1406 as described herein. In stacking 1402 and analysis 1404, with filtering 1406, contours 1408 from repeating features 1410 on a substrate 1411 are aggregated together. A user can choose and set a threshold for filtering 1406 as described above. For example, if a geometric shape (polygon) level KPI threshold is set, the contours with geometric shape (polygon) KPIs that breach the threshold are removed during stacking 1402 and sequential or otherwise subsequent analysis 1404 steps. Similarly, contours from a unit cell or a whole field-of-view (e.g., a die or reticle level image) can be filtered. FIG. 14 illustrates percentile contours 1412 and 1414 (1%, 50%, 99%) calculated based on unfiltered and filtered contour stacks, respectively. With filtering 1406, less reliable contours 1408 are filtered 1406, and percentile contours 1414 are enhanced relative to percentile contours 1412. In other words, as shown in FIG. 14, percentile contours 1414 are more regularly shaped (e.g., smoother, more circular) compared to percentile contours 1412.

As another illustration of the effectiveness of the present systems and methods, in use, the filtering operations above tend to filter approximately 2-3% of the contours in a given substrate pattern. In operational runs, this 2-3% filtering rate remains reasonably constant across runs, and across relative locations in a substrate pattern. Encouragingly, this 2-3% filtering rate decreases to about 1-2% if borders are excluded from the images used for filtering (and again remains reasonably constant across runs and locations).

Returning to FIG. 6, at operation 610 the manufacturing variation or other information is provided to a cost function to facilitate determination of costs associated with individual patterning process variables or metrics. The costs associated with individual patterning process variables or metrics are configured to be used to facilitate optimization of a patterning process. In some embodiments, costs associated with the individual patterning process variables or metrics are configured to be provided to an optimizer to facilitate (e.g. co-) optimization of patterning systems (e.g., lithographic projection apparatuses like the one shown in FIG. 1), or other semiconductor manufacturing processes or systems. In general, an optimizer is a computer algorithm that finds the minimum of a given cost function. An optimizer may be a gradient based non-linear optimizer configured to co-determine multiple patterning process variables, patterning system set points, or other information, for example. An optimizer may be formed by one or more processors configured to balance different possible process variables (e.g., each within their own allowable ranges) against manufacturing capabilities or costs associated with different metrics (e.g., a critical dimension, a pattern placement error, an edge placement error, critical dimension asymmetry, a defect count associated with an etching process, or other metrics).

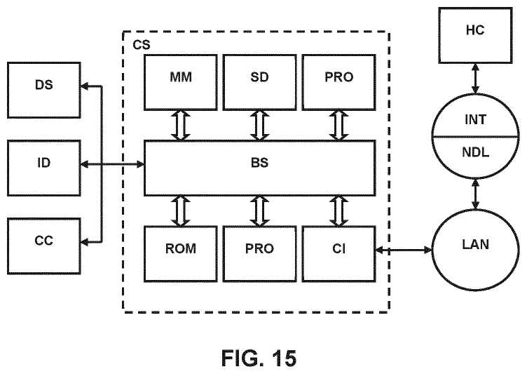

FIG. 15 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have (machine-readable) instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more machine-readable instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, or stored in storage device SD, or other non-volatile storage for later execution. In this manner, computer system CS may obtain application code in the form of a carrier wave.

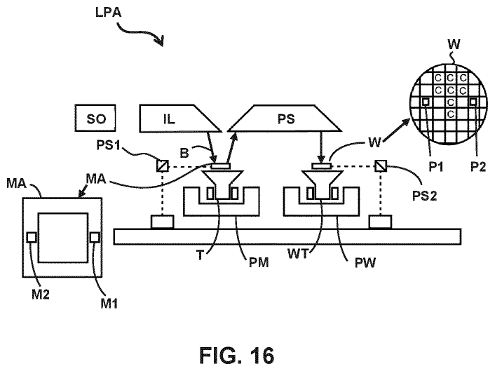

FIG. 16 is a schematic diagram of another lithographic projection apparatus (LPA) that may be used for, or facilitate one or more of the operations described herein. The LPA shown in FIG. 16 is similar to or the same as the apparatus shown in FIG. 1. LPA can include source collector module SO, illumination system (illuminator) IL configured to condition a radiation beam B (e.g. EUV radiation), patterning device table T, substrate table WT, and projection system PS. Patterning device table T can be constructed to support a patterning device (e.g. a mask or a reticle) MA and connected to a first positioner PM configured to accurately position the patterning device. Substrate table (e.g. a wafer table) WT can be constructed to hold a substrate (e.g. a resist coated wafer) W and connected to a second positioner PW configured to accurately position the substrate. Projection system (e.g. a reflective projection system) PS can be configured to project a pattern imparted to the radiation beam B by patterning device MA onto a target portion C (e.g. comprising one or more dies) of the substrate W.

As shown in this example, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium, or tin, with one or more emission lines in the EUV range. In one such method, often termed laser produced plasma (“LPP”), the plasma can be produced by irradiating a fuel, such as a droplet, stream or cluster of material having the line-emitting element, with a laser beam. Source collector module SO may be part of an EUV radiation system including a laser (not shown in FIG. 16), for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation. In this example, the laser may not be considered to form part of the lithographic apparatus and the radiation beam can be passed from the laser to the source collector module with the aid of a beam delivery system comprising, for example, suitable directing mirrors or a beam expander. In other examples, the source may be an integral part of the source collector module, for example when the source is a discharge produced plasma EUV generator, often termed a DPP source.

Illuminator IL may comprise an adjuster for adjusting the angular intensity distribution of the radiation beam. Generally, at least the outer or inner radial extent (commonly referred to as c-outer and c-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held by patterning device table T, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder, or capacitive sensor), the substrate table WT can be moved accurately (e.g. to position different target portions C in the path of radiation beam B). Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode. In step mode, the patterning device table T and the substrate table WT are kept essentially stationary, while an entire pattern imparted to the radiation beam is projected onto a target portion C at one time (e.g., a single static exposure). The substrate table WT is then shifted in the X or Y direction so that a different target portion C can be exposed. In scan mode, the patterning device table T and the substrate table WT are scanned synchronously while a pattern imparted to the radiation beam is projected onto target portion C (i.e. a single dynamic exposure). The velocity and direction of substrate table WT relative to the patterning device table T may be determined by the (de)magnification and image reversal characteristics of the projection system PS. In stationary mode, the patterning device table T is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

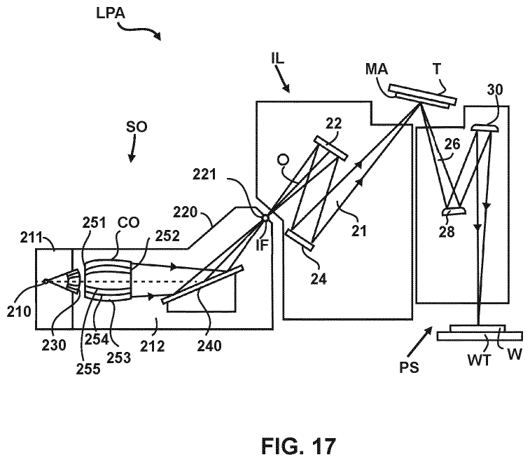

FIG. 17 is a more detailed view of the lithographic projection apparatus shown in FIG. 16 (or FIG. 1). As shown in FIG. 17, the LPA can include the source collector module SO, the illumination system IL, and the projection system PS. The source collector module SO is configured such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier trap 230 (described below) also includes a channel structure. The collector chamber 211 may include a radiation collector CO which may be a grazing incidence collector. Radiation collector CO has an upstream radiation collector side 251 and a downstream radiation collector side 252. Radiation that traverses collector CO can be reflected off a grating spectral filter 240 to be focused on a virtual source point IF along the optical axis indicated by the line “O”. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently, the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the radiation beam 21 at the patterning device MA, held by the patterning device table T, a patterned beam 26 is formed and the patterned beam 26 is imaged by the projection system PS via reflective elements 28, 30 onto a substrate W held by the substrate table WT. More elements than shown may generally be present in illumination optics unit IL and projection system PS. The grating spectral filter 240 may optionally be present, depending upon the type of lithographic apparatus, for example. Further, there may be more mirrors present than those shown in the figures, for example there may be 1-6 additional reflective elements present in the projection system PS than shown in FIG. 17.

Collector optic CO, as illustrated in FIG. 17, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

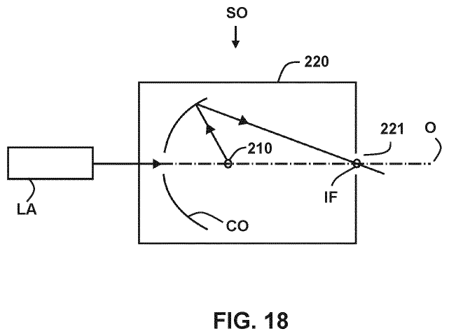

FIG. 18 is a detailed view of source collector module SO of the lithographic projection apparatus LPA (shown in previous figures). Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10″s of eV. The energetic radiation generated during de-excitation and recombination of these ions is emitted from the plasma, collected by a near normal incidence collector optic CO and focused onto the opening 221 in the enclosing structure 220.

Various embodiments are disclosed in the subsequent list of numbered clauses:

1. A method, comprising: receiving substrate pattern inspection images, determining contours based on the substrate pattern inspection images to form a set of inspection contours, wherein determining contours comprises detecting edges of repeating features in the substrate pattern inspection images; and filtering outlier contours from the set of inspection contours, leaving remaining contours in the set of inspection contours after the filtering.
2. The method of any of the previous clauses, further comprising determining a manufacturing variation of the repeating features based on the remaining contours in the set of inspection contours after the filtering. (1)
3. The method of any of the previous clauses, wherein the manufacturing variation is configured to be provided to a cost function to facilitate determination of costs associated with individual patterning process variables, and wherein the costs associated with individual patterning process variables are configured to be used to facilitate optimization of a patterning process. (2)
4. The method of any of the previous clauses, wherein determining the manufacturing variation of the repeating features comprises stacking the remaining contours in the set of inspection contours, and statistically analyzing the stacked remaining contours. (2)
5. The method of any of the previous clauses, wherein the filtering is performed based on individual points on the contours in the set of inspection contours, or geometrical shapes of the contours in the set of inspection contours. (1)
6. The method of any of the previous clauses, wherein the filtering based on the individual points on the contours in the set of inspection contours comprises determining image contrasts or noise levels for pixel locations along a given contour in a substrate pattern inspection image. (5)
7. The method of any of the previous clauses, wherein the filtering based on the geometrical shapes of the contours in the set of inspection contours comprises determining a smoothness of a geometrical shape of a given contour. (5)
8. The method of any of the previous clauses, wherein determining contours based on the substrate pattern inspection images to form the set of inspection contours comprises detecting repeating contours across a unit cell or a reticle associated with a pattern; and wherein filtering the outlier contours from the set of inspection contours comprises filtering each contour associated with an outlier unit cell or outlier reticle. (1)
9. The method of any of the previous clauses, further comprising determining a score for each contour in the set of inspection contours and filtering the outlier contours from the set of inspection contours based on the score. (1)
10. The method of any of the previous clauses, wherein the score is determined based on individual points on the contours in the set of inspection contours, or geometrical shapes of the contours in the set of inspection contours, with reference to the substrate pattern inspection images. (9)
11. The method of any of the previous clauses, wherein the score comprises individual scores for each of multiple points on a contour, and wherein the filtering is based on the individual scores. (9)
12. The method of any of the previous clauses, wherein the score comprises an overall score associated with a geometrical shape of a contour, and wherein the filtering is based on the overall score. (9)
13. The method of any of the previous clauses, wherein the substrate pattern inspection images are generated with an optical inspection system or a charged particle inspection system. (1)
14. The method of any of the previous clauses, wherein the substrate pattern inspection images are generated with the charged particle inspection system, and wherein the charged particle inspection system comprises a scanning electron microscope. (13)
15. A non-transitory computer readable medium having instructions thereon, the instructions when executed by a computer, causing the computer to perform the method of any of the previous clauses. (1)
16. A system comprising one or more processors configured by machine-readable instructions to: receive substrate pattern inspection images, determine contours based on the substrate pattern inspection images to form a set of inspection contours, wherein determining contours comprises detecting edges of repeating features in the substrate pattern inspection images; and filter outlier contours from the set of inspection contours, leaving remaining contours in the set of inspection contours after the filtering.
17. The system of any of the previous clauses, wherein the one or more processors are further configured to determine a manufacturing variation of the repeating features based on the remaining contours in the set of inspection contours after the filtering. (16)
18. The system of any of the previous clauses, wherein the manufacturing variation is configured to be provided to a cost function to facilitate determination of costs associated with individual patterning process variables, and wherein the costs associated with individual patterning process variables are configured to be used to facilitate optimization of a patterning process. (17)
19. The system of any of the previous clauses, wherein determining the manufacturing variation of the repeating features comprises stacking the remaining contours in the set of inspection contours, and statistically analyzing the stacked remaining contours. (17)
20. The system of any of the previous clauses, wherein the filtering is performed based on individual points on the contours in the set of inspection contours, or geometrical shapes of the contours in the set of inspection contours. (16)
21. The system of any of the previous clauses, wherein the filtering based on the individual points on the contours in the set of inspection contours comprises determining image contrasts or noise levels for pixel locations along a given contour in a substrate pattern inspection image. (20)
22. The system of any of the previous clauses, wherein the filtering based on the geometrical shapes of the contours in the set of inspection contours comprises determining a smoothness of a geometrical shape of a given contour. (20)
23. The system of any of the previous clauses, wherein determining contours based on the substrate pattern inspection images to form the set of inspection contours comprises detecting repeating contours across a unit cell or a reticle associated with a pattern; and wherein filtering the outlier contours from the set of inspection contours comprises filtering each contour associated with an outlier unit cell or outlier reticle. (16)
24. The system of any of the previous clauses, wherein the one or more processors are further configured to determine a score for each contour in the set of inspection contours and filter the outlier contours from the set of inspection contours based on the score. (16)
25. The system of any of the previous clauses, wherein the score is determined based on individual points on the contours in the set of inspection contours, or geometrical shapes of the contours in the set of inspection contours, with reference to the substrate pattern inspection images. (24)
26. The system of any of the previous clauses, wherein the score comprises individual scores for each of multiple points on a contour, and wherein the filtering is based on the individual scores. (24)
27. The system of any of the previous clauses, wherein the score comprises an overall score associated with a geometrical shape of a contour, and wherein the filtering is based on the overall score. (24)
28. The system of any of the previous clauses, wherein the substrate pattern inspection images are generated with an optical inspection system or a charged particle inspection system. (16)
29. The system of any of the previous clauses, wherein the substrate pattern inspection images are generated with the charged particle inspection system. (28)
30. The system of any of the previous clauses, wherein the charged particle inspection system comprises a scanning electron microscope. (29)
31. A non-transitory computer readable medium having instructions thereon, the instructions when executed by a computer, causing the computer to perform operations comprising: receiving substrate pattern inspection images, determining contours based on the substrate pattern inspection images to form a set of inspection contours, wherein determining contours comprises detecting edges of repeating features in the substrate pattern inspection images; and filtering outlier contours from the set of inspection contours, leaving remaining contours in the set of inspection contours after the filtering.
32. The medium of any of the previous clauses, the operations further comprising determining a manufacturing variation of the repeating features based on the remaining contours in the set of inspection contours after the filtering. (31)
33. The medium of any of the previous clauses, wherein the manufacturing variation is configured to be provided to a cost function to facilitate determination of costs associated with individual patterning process variables, and wherein the costs associated with individual patterning process variables are configured to be used to facilitate optimization of a patterning process. (32)
34. The medium of any of the previous clauses, wherein determining the manufacturing variation of the repeating features comprises stacking the remaining contours in the set of inspection contours, and statistically analyzing the stacked remaining contours. (32)
35. The medium of any of the previous clauses, wherein the filtering is performed based on individual points on the contours in the set of inspection contours, or geometrical shapes of the contours in the set of inspection contours. (31)
36. The medium of any of the previous clauses, wherein the filtering based on the individual points on the contours in the set of inspection contours comprises determining image contrasts or noise levels for pixel locations along a given contour in a substrate pattern inspection image. (35)
37. The medium of any of the previous clauses, wherein the filtering based on the geometrical shapes of the contours in the set of inspection contours comprises determining a smoothness of a geometrical shape of a given contour. (35)
38. The medium of any of the previous clauses, wherein determining contours based on the substrate pattern inspection images to form the set of inspection contours comprises detecting repeating contours across a unit cell or a reticle associated with a pattern; and wherein filtering the outlier contours from the set of inspection contours comprises filtering each contour associated with an outlier unit cell or outlier reticle. (31)
39. The medium of any of the previous clauses, the operations further comprising determining a score for each contour in the set of inspection contours and filtering the outlier contours from the set of inspection contours based on the score. (31)
40. The medium of any of the previous clauses, wherein the score is determined based on individual points on the contours in the set of inspection contours, or geometrical shapes of the contours in the set of inspection contours, with reference to the substrate pattern inspection images. (39)
41. The medium of any of the previous clauses, wherein the score comprises individual scores for each of multiple points on a contour, and wherein the filtering is based on the individual scores. (39)
42. The medium of any of the previous clauses, wherein the score comprises an overall score associated with a geometrical shape of a contour, and wherein the filtering is based on the overall score. (39)
43. The medium of any of the previous clauses, wherein the substrate pattern inspection images are generated with an optical inspection system or a charged particle inspection system. (31)
44. The medium of any of the previous clauses, wherein the substrate pattern inspection images are generated with the charged particle inspection system. (43)
45. The medium of any of the previous clauses, wherein the charged particle inspection system comprises a scanning electron microscope. (44)
46. A method for electronically filtering outlier contours from a set of inspection contours in substrate pattern inspection images, the method comprising: receiving the substrate pattern inspection images; determining contours based on the substrate pattern inspection images to form the set of inspection contours, wherein determining contours comprises detecting edges of repeating features in the substrate pattern inspection images; filtering the outlier contours from the set of inspection contours, wherein the filtering is performed based on individual points on the contours in the set of inspection contours, or geometrical shapes of the contours in the set of inspection contours; and determining a manufacturing variation of the repeating features based on remaining contours in the set of inspection contours after the filtering.
47. The method of any of the previous clauses, wherein the manufacturing variation is configured to be provided to a cost function to facilitate determination of costs associated with individual patterning process variables, and wherein the costs associated with individual patterning process variables are configured to be used to facilitate optimization of a patterning process. (46)
48. The method of any of the previous clauses, wherein determining the manufacturing variation of the repeating features comprises stacking the remaining contours in the set of inspection contours, and statistically analyzing the stacked remaining contours. (46)
49. The method of any of the previous clauses, wherein the filtering based on the individual points on the contours in the set of inspection contours comprises determining image contrasts or noise levels for pixel locations along a given contour in a substrate pattern inspection image. (46)
50. The method of any of the previous clauses, wherein the filtering based on the geometrical shapes of the contours in the set of inspection contours comprises determining a smoothness of a geometrical shape of the given contour. (46)
51. The method of any of the previous clauses, wherein determining contours based on the substrate pattern inspection images to form the set of inspection contours comprises detecting repeating contours across a unit cell or a reticle associated with a pattern; and wherein filtering the outlier contours from the set of inspection contours comprises filtering each contour associated with an outlier unit cell or outlier reticle. (46)
52. The method of any of the previous clauses, further comprising determining a score for each contour in the set of inspection contours and filtering the outlier contours from the set of inspection contours based on the score. (46)
53. The method of any of the previous clauses, wherein the score is determined based on individual points on the contours in the set of inspection contours, or geometrical shapes of the contours in the set of inspection contours, with reference to the substrate pattern inspection images. (52)
54. The method of any of the previous clauses, wherein the score comprises individual scores for each of multiple points on a contour, and wherein the filtering is based on the individual scores. (52)
55. The method of any of the previous clauses, wherein the score comprises an overall score associated with a geometrical shape of a contour, and wherein the filtering is based on the overall score. (52)
56. The method of any of the previous clauses, wherein the score is indicative of a confidence level or a reliability. (52)
57. The method of any of the previous clauses, wherein the substrate pattern inspection images are generated with an optical inspection system. (46)
58. The method of any of the previous clauses, wherein the optical inspection system is a scatterometer. (57)
59. The method of any of the previous clauses, wherein the substrate pattern inspection images are generated with a charged particle inspection system. (46)
60. The method of any of the previous clauses, wherein the charged particle inspection system comprises a scanning electron microscope. (59)
61. A non-transitory computer readable medium having instructions thereon, the instructions when executed by a computer, causing the computer to electronically filter outlier contours from a set of inspection contours in substrate pattern inspection images, the instructions causing operations comprising: receiving the substrate pattern inspection images; determining contours based on the substrate pattern inspection images to form the set of inspection contours, wherein determining contours comprises detecting edges of repeating features in the substrate pattern inspection images; filtering the outlier contours from the set of inspection contours, wherein the filtering is performed based on individual points on the contours in the set of inspection contours, or geometrical shapes of the contours in the set of inspection contours; and determining a manufacturing variation of the repeating features based on remaining contours in the set of inspection contours after the filtering.
62. The medium of any of the previous clauses, wherein the manufacturing variation is configured to be provided to a cost function to facilitate determination of costs associated with individual patterning process variables, and wherein the costs associated with individual patterning process variables are configured to be used to facilitate optimization of a patterning process. (61)
63. The medium of any of the previous clauses, wherein determining the manufacturing variation of the repeating features comprises stacking the remaining contours in the set of inspection contours, and statistically analyzing the stacked remaining contours. (61)
64. The medium of any of the previous clauses, wherein the filtering based on the individual points on the contours in the set of inspection contours comprises determining image contrasts or noise levels for pixel locations along a given contour in a substrate pattern inspection image. (61)
65. The medium of any of the previous clauses, wherein the filtering based on the geometrical shapes of the contours in the set of inspection contours comprises determining a smoothness of a geometrical shape of a given contour. (61)
66. The medium of any of the previous clauses, wherein determining contours based on the substrate pattern inspection images to form the set of inspection contours comprises detecting repeating contours across a unit cell or a reticle associated with a pattern; and wherein filtering the outlier contours from the set of inspection contours comprises filtering each contour associated with an outlier unit cell or outlier reticle. (61)
67. The medium of any of the previous clauses, further comprising determining a score for each contour in the set of inspection contours and filtering the outlier contours from the set of inspection contours based on the score. (61)
68. The medium of any of the previous clauses, wherein the score is determined based on individual points on the contours in the set of inspection contours, or geometrical shapes of the contours in the set of inspection contours, with reference to the substrate pattern inspection images. (67)
69. The medium of any of the previous clauses, wherein the score comprises individual scores for each of multiple points on a contour, and wherein the filtering is based on the individual scores. (67)
70. The medium of any of the previous clauses, wherein the score comprises an overall score associated with a geometrical shape of a contour, and wherein the filtering is based on the overall score. (67)
71. The medium of any of the previous clauses, wherein the score is indicative of a confidence level or a reliability. (67)
72. The medium of any of the previous clauses, wherein the substrate pattern inspection images are generated with an optical inspection system. (61)
73. The medium of any of the previous clauses, wherein the optical inspection system is a scatterometer. (72)
74. The medium of any of the previous clauses, wherein the substrate pattern inspection images are generated with a charged particle inspection system. (61)
75. The medium of any of the previous clauses, wherein the charged particle inspection system comprises a scanning electron microscope. (74)
76. A system for electronically filtering outlier contours from a set of inspection contours in substrate pattern inspection images, the system comprising one or more processors configured by machine-readable instructions to: receive the substrate pattern inspection images; determine contours based on the substrate pattern inspection images to form the set of inspection contours, wherein determining contours comprises detecting edges of repeating features in the substrate pattern inspection images; filter the outlier contours from the set of inspection contours, wherein the filtering is performed based on individual points on the contours in the set of inspection contours, or geometrical shapes of the contours in the set of inspection contours; and determine a manufacturing variation of the repeating features based on remaining contours in the set of inspection contours after the filtering.
77. The system of any of the previous clauses, wherein the manufacturing variation is configured to be provided to a cost function to facilitate determination of costs associated with individual patterning process variables, and wherein the costs associated with individual patterning process variables are configured to be used to facilitate optimization of a patterning process. (76)
78. The system of any of the previous clauses, wherein determining the manufacturing variation of the repeating features comprises stacking the remaining contours in the set of inspection contours, and statistically analyzing the stacked remaining contours. (76)
79. The system of any of the previous clauses, wherein the filtering based on the individual points on the contours in the set of inspection contours comprises determining image contrasts or noise levels for pixel locations along a given contour in a substrate pattern inspection image. (76)
80. The system of any of the previous clauses, wherein the filtering based on the geometrical shapes of the contours in the set of inspection contours comprises determining a smoothness of a geometrical shape of a given contour. (76)
81. The system of any of the previous clauses, wherein determining contours based on the substrate pattern inspection images to form the set of inspection contours comprises detecting repeating contours across a unit cell or a reticle associated with a pattern; and wherein filtering the outlier contours from the set of inspection contours comprises filtering each contour associated with an outlier unit cell or outlier reticle. (76)
82. The system of any of the previous clauses, wherein the one or more processors are further configured to determine a score for each contour in the set of inspection contours and filter the outlier contours from the set of inspection contours based on the score. (76)
83. The system of any of the previous clauses, wherein the score is determined based on individual points on the contours in the set of inspection contours, or geometrical shapes of the contours in the set of inspection contours, with reference to the substrate pattern inspection images. (82)
84. The system of any of the previous clauses, wherein the score comprises individual scores for each of multiple points on a contour, and wherein the filtering is based on the individual scores. (82)
85. The system of any of the previous clauses, wherein the score comprises an overall score associated with a geometrical shape of a contour, and wherein the filtering is based on the overall score. (82)
86. The system of any of the previous clauses, wherein the score is indicative of a confidence level or a reliability. (82)
87. The system of any of the previous clauses, wherein the substrate pattern inspection images are generated with an optical inspection system. (76)
88. The system of any of the previous clauses, wherein the optical inspection system is a scatterometer. (87)
89. The system of any of the previous clauses, wherein the substrate pattern inspection images are generated with a charged particle inspection system. (76)
90. The system of any of the previous clauses, wherein the charged particle inspection system comprises a scanning electron microscope. (89)
91. A non-transitory computer readable medium having instructions thereon, the instructions when executed by a computer, causing the computer to electronically filter outlier contours from a set of inspection contours in substrate pattern inspection images, the filtering configured to enhance a determination of manufacturing variation in, and optimization of, a patterning process compared to prior patterning processes, the instructions causing operations comprising: receiving the substrate pattern inspection images, wherein the substrate pattern inspection images are generated with a charged particle inspection system; determining contours based on the substrate pattern inspection images to form the set of inspection contours, wherein determining contours comprises detecting edges of repeating features in the substrate pattern inspection images; filtering the outlier contours from the set of inspection contours, wherein the filtering is performed based on individual points on the contours in the set of inspection contours, or geometrical shapes of the contours in the set of inspection contours; and determining a manufacturing variation of the repeating features based on remaining contours in the set of inspection contours after the filtering, wherein the manufacturing variation is configured to be provided to a cost function to facilitate determination of costs associated with individual patterning process variables, and wherein the costs associated with individual patterning process variables are configured to be used to facilitate the optimization of the patterning process.
92. The medium of any of the previous clauses, wherein: filtering based on individual points on the contours in the set of inspection contours comprises determining characteristics of the substrate pattern inspection images including determining image contrasts or noise levels for pixel locations along the given contour in a substrate pattern inspection image; and filtering based on geometrical shapes of the contours in the set of inspection contours comprises determining a smoothness of a geometrical shape of the given contour. (91)
93. The medium of any of the previous clauses, the operations further comprising determining a score for each contour in the set of inspection contours based on the individual points on the contours in the set of inspection contours, or the geometrical shapes of the contours in the set of inspection contours; and filtering the outlier contours from the set of inspection contours based on the score. (91)
94. The medium of any of the previous clauses, wherein determining the manufacturing variation of the repeating features comprises stacking the remaining contours in the set of inspection contours, and statistically analyzing the stacked remaining contours. (91)
95. The medium of any of the previous clauses, wherein the charged particle inspection system comprises a scanning electron microscope. (91)
96. A method for electronically filtering outlier contours from a set of inspection contours in substrate pattern inspection images, the filtering configured to enhance a determination of manufacturing variation in, and optimization of, a patterning process compared to prior patterning processes, the method comprising: receiving the substrate pattern inspection images, wherein the substrate pattern inspection images are generated with a charged particle inspection system; determining contours based on the substrate pattern inspection images to form the set of inspection contours, wherein determining contours comprises detecting edges of repeating features in the substrate pattern inspection images; filtering the outlier contours from the set of inspection contours, wherein the filtering is performed based on individual points on the contours in the set of inspection contours, or geometrical shapes of the contours in the set of inspection contours; and determining a manufacturing variation of the repeating features based on remaining contours in the set of inspection contours after the filtering, wherein the manufacturing variation is configured to be provided to a cost function to facilitate determination of costs associated with individual patterning process variables, and wherein the costs associated with individual patterning process variables are configured to be used to facilitate the optimization of the patterning process.
97. The method of any of the previous clauses, wherein: filtering based on individual points on the contours in the set of inspection contours comprises determining characteristics of the substrate pattern inspection images including determining image contrasts or noise levels for pixel locations along a given contour in a substrate pattern inspection image; and filtering based on geometrical shapes of the contours in the set of inspection contours comprises determining a smoothness of a geometrical shape of the given contour. (96)
98. The method of any of the previous clauses, the operations further comprising determining a score for each contour in the set of inspection contours based on the individual points on the contours in the set of inspection contours, or the geometrical shapes of the contours in the set of inspection contours; and filtering the outlier contours from the set of inspection contours based on the score. (96)
99. The method of any of the previous clauses, wherein determining the manufacturing variation of the repeating features comprises stacking the remaining contours in the set of inspection contours, and statistically analyzing the stacked remaining contours. (96)
100. The method of any of the previous clauses, wherein the charged particle inspection system comprises a scanning electron microscope. (96)
101. A system for electronically filtering outlier contours from a set of inspection contours in substrate pattern inspection images, the filtering configured to enhance a determination of manufacturing variation in, and optimization of, a patterning process compared to prior patterning processes, the system comprising one or more processors configured by machine-readable instructions to: receive the substrate pattern inspection images, wherein the substrate pattern inspection images are generated with a charged particle inspection system; determine contours based on the substrate pattern inspection images to form the set of inspection contours, wherein determining contours comprises detecting edges of repeating features in the substrate pattern inspection images; filter the outlier contours from the set of inspection contours, wherein the filtering is performed based on individual points on the contours in the set of inspection contours, or geometrical shapes of the contours in the set of inspection contours; and determine a manufacturing variation of the repeating features based on remaining contours in the set of inspection contours after the filtering, wherein the manufacturing variation is configured to be provided to a cost function to facilitate determination of costs associated with individual patterning process variables, and wherein the costs associated with individual patterning process variables are configured to be used to facilitate the optimization of the patterning process.
102. The system of any of the previous clauses, wherein: filtering based on individual points on the contours in the set of inspection contours comprises determining characteristics of the substrate pattern inspection images including determining image contrasts or noise levels for pixel locations along a given contour in a substrate pattern inspection image; and filtering based on geometrical shapes of the contours in the set of inspection contours comprises determining a smoothness of a geometrical shape of the given contour. (101)
103. The system of any of the previous clauses, wherein the one or more processors are further configured to determine a score for each contour in the set of inspection contours based on the individual points on the contours in the set of inspection contours, or the geometrical shapes of the contours in the set of inspection contours; and filter the outlier contours from the set of inspection contours based on the score. (101)
104. The system of any of the previous clauses, wherein determining the manufacturing variation of the repeating features comprises stacking the remaining contours in the set of inspection contours, and statistically analyzing the stacked remaining contours. (101)
105. The system of any of the previous clauses, wherein the charged particle inspection system comprises a scanning electron microscope. (101)
106. A method of analyzing a manufacturing variation of a feature comprising: receiving scanning electron microscope (SEM) images that include identical features; determining a contour of each of the identical features; filtering a first subset of the contours leaving a remainder second subset of the contours; and determining a manufacturing variation of the identical features based on the second subset of the contours.
107. The method of any of the previous clauses, further comprising: determining a score for each of the contours based on characteristics of the contours, wherein the filtering of the first subset is based on the scores. (106)
108. The method of any of the previous clauses, further comprising: determining a score for each of multiple points on each of the contours based on characteristics of the contours, wherein the filtering of the first subset is based on the scores. (106)
109. A non-transitory computer readable medium having instructions thereon, the instructions when executed by a computer, causing operations comprising: receiving scanning electron microscope (SEM) images that include identical features; determining a contour of each of the identical features; filtering a first subset of the contours leaving a remainder second subset of the contours; and determining a manufacturing variation of the identical features based on the second subset of the contours.
110. The medium of any of the previous clauses, the operations further comprising: determining a score for each of the contours based on characteristics of the contours, wherein the filtering of the first subset is based on the scores. (109)
111. The medium of any of the previous clauses, the operations further comprising: determining a score for each of multiple points on each of the contours based on characteristics of the contours, wherein the filtering of the first subset is based on the scores. (109)
112. A system for analyzing a manufacturing variation of a feature, the system comprising one or more processors configured by machine-readable instructions to: receive scanning electron microscope (SEM) images that include identical features; determine a contour of each of the identical features; filter a first subset of the contours leaving a remainder second subset of the contours; and determine a manufacturing variation of the identical features based on the second subset of the contours.
113. The system of any of the previous clauses, wherein the one or more processors are further configured to: determine a score for each of the contours based on characteristics of the contours, wherein the filtering of the first subset is based on the scores. (112)
114. The system of any of the previous clauses, wherein the one or more processors are further configured to: determine a score for each of multiple points on each of the contours based on characteristics of the contours, wherein the filtering of the first subset is based on the scores. (112)
115. A method for enhancing a patterning process, the method comprising: receiving substrate pattern inspection images, determining contours in the substrate pattern inspection images to form a set of inspection contours, wherein determining contours comprises detecting edges of features in the substrate pattern inspection images; and filtering outlier contours from the set of inspection contours.
116. The method of any of the previous clauses, wherein: a determined contour comprises vertices; detecting the edges of the features comprises identifying the vertices in the determined contours; and the filtering of the outlier contours is based on the vertices. (115)
117. The method of any of the previous clauses, further comprising determining angles formed at vertices of the determined contours, and filtering the outlier contours from the set of inspection contours based on the angles. (115)
118. The method of any of the previous clauses, wherein filtering the outlier contours from the set of inspection contours is based on comparisons of the determined angles to an angle threshold, and wherein determined contours with an angle at a vertex smaller than the angle threshold are determined to be outlier contours and filtered from the set of inspection contours. (117)
119. The method of any of the previous clauses, wherein the threshold angle is 120, 90, 60, or 45 degrees. (118)
120. The method of any of the previous clauses, further comprising determining distances between adjacent vertices of the determined contours, and filtering the outlier contours from the set of inspection contours based on the distances. (115)
121. The method of any of the previous clauses, wherein filtering the outlier contours from the set of inspection contours is based on comparisons of the determined distances to a distance threshold, and wherein determined contours with a distance that breaches the distance threshold are determined to be outlier contours and filtered from the set of inspection contours. (120)
122. The method of any of the previous clauses, wherein the distance threshold comprises: a distance that is a given number of times, or a percentage, larger or smaller than an average distance between vertices; or a distance that corresponds to a contour edge roughness parameter. (121)
123. The method of any of the previous clauses, further comprising determining centers of gravity of the determined contours, and filtering the outlier contours from the set of inspection contours based a relationship between a center of gravity and one or more vertices of a given contour. (115)
124. The method of any of the previous clauses, wherein the filtering based on the relationship comprises filtering the given contour from the set of inspection contours responsive to the given contour having one or more vertices with distances from the center of gravity that breach a center of gravity distance threshold. (123)
125. The method of any of the previous clauses, wherein the center of gravity distance threshold comprises a distance that is a given number of times, or a percentage, larger or smaller than an average distance between vertices and the center of gravity. (124)
126. The method of any of the previous clauses, further comprising determining centers of gravity of the determined contours, fitting expected contour shapes to the determined contours based on the centers of gravity, and filtering the outlier contours from the set of inspection contours based a relationship between a fitted expected contour and vertices of a given contour. (115)
127. The method of any of the previous clauses, further comprising determining centers of gravity of the determined contours, fitting circles or ellipses to the determined contours based on the centers of gravity, and filtering the outlier contours from the set of inspection contours based on a relationship between a fitted circle or ellipse and vertices of a given contour. (115)
128. The method of any of the previous clauses, wherein the filtering based on the relationship comprises filtering the given contour from the set of inspection contours responsive to the given contour having one or more vertices with distances from the fitted circle or ellipse that breach a fitting distance threshold. (127)
129. The method of any of the previous clauses, wherein the fitting distance threshold comprises a distance that is a given number of times, or a percentage, larger or smaller than an average distance between vertices and the fitted circle or ellipse. (128)
130. The method of any of the previous clauses, wherein the contour comprises a polygon. (115)
131. The method of any of the previous clauses, wherein the substrate pattern inspection images are generated with an optical inspection system or a charged particle inspection system. (115)
132. The method of any of the previous clauses, wherein the substrate pattern inspection images are generated with the charged particle inspection system, and wherein the charged particle inspection system comprises a scanning electron microscope. (131)
133. The method of any of the previous clauses, further comprising determining a manufacturing variation of the features based on remaining contours in the set of inspection contours after the filtering. (115)
134. The method of any of the previous clauses, wherein the manufacturing variation is configured to be provided to a cost function to facilitate determination of costs associated with individual patterning process variables, and wherein the costs associated with individual patterning process variables are configured to be used to facilitate optimization of a patterning process. (133)
135. The method of any of the previous clauses, wherein determining contours in the substrate pattern inspection images to form the set of inspection contours comprises detecting repeating contours across a unit cell or a reticle associated with a pattern; and wherein filtering the outlier contours from the set of inspection contours comprises filtering each contour, or portion of a contour, associated with an outlier unit cell or outlier reticle. (115)
136. A non-transitory computer readable medium having instructions thereon, the instructions when executed by a computer, causing the computer to: receive substrate pattern inspection images, determine contours in the substrate pattern inspection images to form a set of inspection contours, wherein determining contours comprises detecting edges of features in the substrate pattern inspection images; and filter outlier contours from the set of inspection contours.
137. The medium of any of the previous clauses, wherein: a determined contour comprises vertices; detecting the edges of the features comprises identifying the vertices in the determined contours; and the filtering of the outlier contours is based on the vertices. (136)
138. The medium of any of the previous clauses, the instructions further causing the computer to determine angles formed at vertices of the determined contours, and filter the outlier contours from the set of inspection contours based on the angles. (136)
139. The medium of any of the previous clauses, wherein filtering the outlier contours from the set of inspection contours is based on comparisons of the determined angles to an angle threshold, and wherein determined contours with an angle at a vertex smaller than the angle threshold are determined to be outlier contours and filtered from the set of inspection contours. (138)
140. The medium of any of the previous clauses, wherein the threshold angle is 120, 90, 60, or 45 degrees. (139)
141. The medium of any of the previous clauses, the instructions further causing the computer to determine distances between adjacent vertices of the determined contours, and filter the outlier contours from the set of inspection contours based on the distances. (136)
142. The medium of any of the previous clauses, wherein filtering the outlier contours from the set of inspection contours is based on comparisons of the determined distances to a distance threshold, and wherein determined contours with a distance that breaches the distance threshold are determined to be outlier contours and filtered from the set of inspection contours. (141)
143. The medium of any of the previous clauses, wherein the distance threshold comprises: a distance that is a given number of times, or a percentage, larger or smaller than an average distance between vertices; or a distance that corresponds to a contour edge roughness parameter. (142)
144. The medium of any of the previous clauses, the instructions further causing the computer to determine centers of gravity of the determined contours, and filter the outlier contours from the set of inspection contours based a relationship between a center of gravity and one or more vertices of a given contour. (136)
145. The medium of any of the previous clauses, wherein the filtering based on the relationship comprises filtering the given contour from the set of inspection contours responsive to the given contour having one or more vertices with distances from the center of gravity that breach a center of gravity distance threshold. (144)
146. The medium of any of the previous clauses, wherein the center of gravity distance threshold comprises a distance that is a given number of times, or a percentage, larger or smaller than an average distance between vertices and the center of gravity. (145)
147. The medium of any of the previous clauses, the instructions further causing the computer to determine centers of gravity of the determined contours, fit expected contour shapes to the determined contours based on the centers of gravity, and filter the outlier contours from the set of inspection contours based a relationship between a fitted expected contour and vertices of a given contour. (136)
148. The medium of any of the previous clauses, the instructions further causing the computer to determine centers of gravity of the determined contours, fit circles or ellipses to the determined contours based on the centers of gravity, and filter the outlier contours from the set of inspection contours based on a relationship between a fitted circle or ellipse and vertices of a given contour. (136)
149. The medium of any of the previous clauses, wherein the filtering based on the relationship comprises filtering the given contour from the set of inspection contours responsive to the given contour having one or more vertices with distances from the fitted circle or ellipse that breach a fitting distance threshold. (148)
150. The medium of any of the previous clauses, wherein the fitting distance threshold comprises a distance that is a given number of times, or a percentage, larger or smaller than an average distance between vertices and the fitted circle or ellipse. (149)
151. The medium of any of the previous clauses, wherein the contour comprises a polygon. (136)
152. The medium of any of the previous clauses, wherein the substrate pattern inspection images are generated with an optical inspection system or a charged particle inspection system. (136)
153. The medium of any of the previous clauses, wherein the substrate pattern inspection images are generated with the charged particle inspection system, and wherein the charged particle inspection system comprises a scanning electron microscope. (152)
154. The medium of any of the previous clauses, the instructions further causing the computer to determine a manufacturing variation of the features based on remaining contours in the set of inspection contours after the filtering. (136)
155. The medium of any of the previous clauses, wherein the manufacturing variation is configured to be provided to a cost function to facilitate determination of costs associated with individual patterning process variables, and wherein the costs associated with individual patterning process variables are configured to be used to facilitate optimization of a patterning process. (154)
156. The medium of any of the previous clauses, wherein determining contours in the substrate pattern inspection images to form the set of inspection contours comprises detecting repeating contours across a unit cell or a reticle associated with a pattern; and wherein filtering the outlier contours from the set of inspection contours comprises filtering each contour, or portion of a contour, associated with an outlier unit cell or outlier reticle. (136)
157. A system for enhancing a patterning process, the system comprising one or more processors configured by machine readable instructions to: receive substrate pattern inspection images, determine contours in the substrate pattern inspection images to form a set of inspection contours, wherein determining contours comprises detecting edges of features in the substrate pattern inspection images; and filter outlier contours from the set of inspection contours.
158. The system of claim 43, wherein: a determined contour comprises vertices; detecting the edges of the features comprises identifying the vertices in the determined contours; and the filtering of the outlier contours is based on the vertices. (157)
159. The system of any of the previous clauses, the one or more processors further configured to determine angles formed at vertices of the determined contours, and filter the outlier contours from the set of inspection contours based on the angles. (157)
160. The system of any of the previous clauses, wherein filtering the outlier contours from the set of inspection contours is based on comparisons of the determined angles to an angle threshold, and wherein determined contours with an angle at a vertex smaller than the angle threshold are determined to be outlier contours and filtered from the set of inspection contours. (159)
161. The system of any of the previous clauses, wherein the threshold angle is 120, 90, 60, or 45 degrees. (160)
162. The system of any of the previous clauses, the one or more processors further configured to determine distances between adjacent vertices of the determined contours, and filter the outlier contours from the set of inspection contours based on the distances. (157)
163. The system of any of the previous clauses, wherein filtering the outlier contours from the set of inspection contours is based on comparisons of the determined distances to a distance threshold, and wherein determined contours with a distance that breaches the distance threshold are determined to be outlier contours and filtered from the set of inspection contours. (162)
164. The system of any of the previous clauses, wherein the distance threshold comprises: a distance that is a given number of times, or a percentage, larger or smaller than an average distance between vertices; or a distance that corresponds to a contour edge roughness parameter. (163)
165. The system of any of any of the previous clauses, the one or more processors further configured to determine centers of gravity of the determined contours, and filter the outlier contours from the set of inspection contours based a relationship between a center of gravity and one or more vertices of a given contour. (157)
166. The system of any of the previous clauses, wherein the filtering based on the relationship comprises filtering the given contour from the set of inspection contours responsive to the given contour having one or more vertices with distances from the center of gravity that breach a center of gravity distance threshold. (165)
167. The system of any of the previous clauses, wherein the center of gravity distance threshold comprises a distance that is a given number of times, or a percentage, larger or smaller than an average distance between vertices and the center of gravity. (166)
168. The system of any of the previous clauses, the one or more processors further configured to determine centers of gravity of the determined contours, fit expected contour shapes to the determined contours based on the centers of gravity, and filter the outlier contours from the set of inspection contours based a relationship between a fitted expected contour and vertices of a given contour. (157)
169. The system of any of the previous clauses, the one or more processors further configured to determine centers of gravity of the determined contours, fit circles or ellipses to the determined contours based on the centers of gravity, and filter the outlier contours from the set of inspection contours based a relationship between a fitted circle or ellipse and vertices of a given contour. (157)
170. The system of any of the previous clauses, wherein the filtering based on the relationship comprises filtering the given contour from the set of inspection contours responsive to the given contour having one or more vertices with distances from the fitted circle or ellipse that breach a fitting distance threshold. (169)
171. The system of any of the previous clauses, wherein the fitting distance threshold comprises a distance that is a given number of times, or a percentage, larger or smaller than an average distance between vertices and the fitted circle or ellipse. (170)
172. The system of any of the previous clauses, wherein the contour comprises a polygon. (157)
173. The system of any of the previous clauses, wherein the substrate pattern inspection images are generated with an optical inspection system or a charged particle inspection system. (157)
174. The system of any of the previous clauses, wherein the substrate pattern inspection images are generated with the charged particle inspection system, and wherein the charged particle inspection system comprises a scanning electron microscope. (173)
175. The system of any of the previous clauses, the one or more processors further configured to determine a manufacturing variation of the features based on remaining contours in the set of inspection contours after the filtering. (157)
176. The system of any of the previous clauses, wherein the manufacturing variation is configured to be provided to a cost function to facilitate determination of costs associated with individual patterning process variables, and wherein the costs associated with individual patterning process variables are configured to be used to facilitate optimization of a patterning process. (175)
177. The system of any of the previous clauses, wherein determining contours in the substrate pattern inspection images to form the set of inspection contours comprises detecting repeating contours across a unit cell or a reticle associated with a pattern; and wherein filtering the outlier contours from the set of inspection contours comprises filtering each contour, or portion of a contour, associated with an outlier unit cell or outlier reticle. (157)
178. A method for enhancing a patterning process, the method comprising: receiving substrate pattern inspection images, determining contours in the substrate pattern inspection images to form a set of inspection contours, wherein determining contours comprises detecting edges of features in the substrate pattern inspection images; and filtering outlier contours from the set of inspection contours.
179. The method of any of the previous clauses, wherein: a determined contour comprises vertices; detecting the edges of the features comprises identifying the vertices in the determined contours; and the filtering of the outlier contours is based on the vertices. (178)
180. The method of any of the previous clauses, further comprising determining angles formed at vertices of the determined contours, and filtering the outlier contours from the set of inspection contours based on the angles. (178)
181. The method of any of the previous clauses, wherein filtering the outlier contours from the set of inspection contours is based on comparisons of the determined angles to an angle threshold, and wherein determined contours with an angle at a vertex smaller than the angle threshold are determined to be outlier contours and filtered from the set of inspection contours. (180)
182. The method of any of the previous clauses, further comprising determining distances between adjacent vertices of the determined contours, and filtering the outlier contours from the set of inspection contours based on the distances. (178)
183. The method of any of the previous clauses, wherein filtering the outlier contours from the set of inspection contours is based on comparisons of the determined distances to a distance threshold, and wherein determined contours with a distance that breaches the distance threshold are determined to be outlier contours and filtered from the set of inspection contours. (182)
184. The method of any of the previous clauses, wherein the distance threshold comprises: a distance that is a given number of times, or a percentage, larger or smaller than an average distance between vertices; or a distance that corresponds to a contour edge roughness parameter. (183)
185. The method of any of the previous clauses, further comprising determining centers of gravity of the determined contours, and filtering the outlier contours from the set of inspection contours based a relationship between a center of gravity and one or more vertices of a given contour. (178)
186. The method of any of the previous clauses, wherein the filtering based on the relationship comprises filtering the given contour from the set of inspection contours responsive to the given contour having one or more vertices with distances from the center of gravity that breach a center of gravity distance threshold. (185)
187. The method of any of the previous clauses, wherein the center of gravity distance threshold comprises a distance that is a given number of times, or a percentage, larger or smaller than an average distance between vertices and the center of gravity. (186)
188. The method of any of the previous clauses, further comprising determining centers of gravity of the determined contours, fitting circles or ellipses to the determined contours based on the centers of gravity, and filtering the outlier contours from the set of inspection contours based on a relationship between a fitted circle or ellipse and vertices of a given contour. (178)
189. The method of any of the previous clauses, wherein the filtering based on the relationship comprises filtering the given contour from the set of inspection contours responsive to the given contour having one or more vertices with distances from the fitted circle or ellipse that breach a fitting distance threshold. (188)
190. The method of any of the previous clauses, wherein the substrate pattern inspection images are generated with the charged particle inspection system, and wherein the charged particle inspection system comprises a scanning electron microscope. (178)
191. The method of any of the previous clauses, further comprising determining a manufacturing variation of the features based on remaining contours in the set of inspection contours after the filtering, wherein the manufacturing variation is configured to be provided to a cost function to facilitate determination of costs associated with individual patterning process variables, and wherein the costs associated with individual patterning process variables are configured to be used to facilitate optimization of a patterning process. (178)
192. The method of any of the previous clauses, wherein determining contours in the substrate pattern inspection images to form the set of inspection contours comprises detecting repeating contours across a unit cell or a reticle associated with a pattern; and wherein filtering the outlier contours from the set of inspection contours comprises filtering each contour, or portion of a contour, associated with an outlier unit cell or outlier reticle. (178)
193. A non-transitory computer readable medium having instructions thereon, the instructions when executed by a computer, causing the computer to electronically filter outlier contours from a set of inspection contours in substrate pattern inspection images, the filtering configured to enhance a determination of manufacturing variation in, and optimization of, a patterning process compared to prior patterning processes, the instructions causing operations comprising: receiving the substrate pattern inspection images, wherein the substrate pattern inspection images are generated with a charged particle inspection system; determining contours in the substrate pattern inspection images to form the set of inspection contours, wherein determining contours comprises detecting edges of features in the substrate pattern inspection images, the edges comprising vertices of the contours; filtering the outlier contours from the set of inspection contours, wherein the filtering is performed based on the vertices; and determining a manufacturing variation of the features based on remaining contours in the set of inspection contours after the filtering, wherein the manufacturing variation is configured to be provided to a cost function to facilitate determination of costs associated with individual patterning process variables, and wherein the costs associated with individual patterning process variables are configured to be used to facilitate the optimization of the patterning process.
194. The medium of any of the previous clauses, the operations further comprising determining angles formed at the vertices of the determined contours, and filtering the outlier contours from the set of inspection contours based on the angles. (193)
195. The medium of any of the previous clauses, the operations further comprising determining distances between adjacent vertices of the determined contours, and filtering the outlier contours from the set of inspection contours based on the distances. (193)
196. The medium of any of the previous clauses, the operations further comprising determining centers of gravity of the determined contours, fitting circles or ellipses to the determined contours based on the centers of gravity, and filtering the outlier contours from the set of inspection contours based a relationship between a fitted circle or ellipse and vertices of a given contour. (193)
197. The medium of any of the previous clauses, wherein the charged particle inspection system comprises a scanning electron microscope. (193)

The concepts disclosed herein may be used with any imaging, etching, polishing, inspection, etc. system for sub wavelength features, and may be useful with emerging imaging technologies capable of producing increasingly shorter wavelengths. Emerging technologies include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, the point level and feature level filtering described herein may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

1. A method for enhancing a patterning process, the method comprising:
receiving substrate pattern inspection images,
determining, by a hardware computer system, contours in the substrate pattern inspection images to form a set of inspection contours, wherein determining contours comprises detecting edges of features in the substrate pattern inspection images; and
filtering outlier contours from the set of inspection contours.

2. The method of claim 1, wherein:
a determined contour comprises vertices;
detecting the edges of the features comprises identifying the vertices in the determined contours; and
the filtering of the outlier contours is based on the vertices.

3. The method of claim 1, further comprising determining angles formed at vertices of the determined contours, and filtering the outlier contours from the set of inspection contours based on the angles.

4. The method of claim 3, wherein filtering the outlier contours from the set of inspection contours is based on comparisons of the determined angles to an angle threshold, and wherein determined contours with an angle at a vertex smaller than the angle threshold are determined to be outlier contours and filtered from the set of inspection contours.

5. The method of claim 1, further comprising determining distances between adjacent vertices of the determined contours, and filtering the outlier contours from the set of inspection contours based on the distances.

6. The method of claim 5, wherein filtering the outlier contours from the set of inspection contours is based on comparisons of the determined distances to a distance threshold, and wherein determined contours with a distance that breaches the distance threshold are determined to be outlier contours and filtered from the set of inspection contours.

7. The method of claim 6, wherein the distance threshold comprises:
a distance that is a given number of times, or a percentage, larger or smaller than an average distance between vertices; or
a distance that corresponds to a contour edge roughness parameter.

8. The method of claim 1, further comprising determining centers of gravity of the determined contours, and filtering the outlier contours from the set of inspection contours based on a relationship between a center of gravity and one or more vertices of a given contour.

9. The method of claim 8, wherein the filtering based on the relationship comprises filtering the given contour from the set of inspection contours responsive to the given contour having one or more vertices with distances from the center of gravity that breach a center of gravity distance threshold.

10. The method of claim 9, wherein the center of gravity distance threshold comprises a distance that is a given number of times, or a percentage, larger or smaller than an average distance between vertices and the center of gravity.

11. The method of claim 1, further comprising determining centers of gravity of the determined contours, fitting circles or ellipses to the determined contours based on the centers of gravity, and filtering the outlier contours from the set of inspection contours based on a relationship between a fitted circle or ellipse and vertices of a given contour.

12. The method of claim 11, wherein the filtering based on the relationship comprises filtering the given contour from the set of inspection contours responsive to the given contour having one or more vertices with distances from the fitted circle or ellipse that breach a fitting distance threshold.

13. The method of claim 1, wherein the substrate pattern inspection images are generated with a charged particle inspection system, and wherein the charged particle inspection system comprises a scanning electron microscope.

14. The method of claim 1, further comprising determining a manufacturing variation of the features based on remaining contours in the set of inspection contours after the filtering, wherein the manufacturing variation is configured to be provided to a cost function to facilitate determination of costs associated with individual patterning process variables, and wherein the costs associated with individual patterning process variables are configured to be used to facilitate optimization of a patterning process.

15. The method of claim 1, wherein determining contours in the substrate pattern inspection images to form the set of inspection contours comprises detecting repeating contours across a unit cell or a reticle associated with a pattern; and wherein filtering the outlier contours from the set of inspection contours comprises filtering each contour, or portion of a contour, associated with an outlier unit cell or outlier reticle.

16. A system comprising one or more processors configured by machine-readable instructions to at least:
receive substrate pattern inspection images;
determine contours based on the substrate pattern inspection images to form a set of inspection contours, wherein determination of contours comprises detection of edges of repeating features in the substrate pattern inspection images; and
filter outlier contours from the set of inspection contours.

17. The system of claim 16, wherein the one or more processors are further configured to determine a manufacturing variation of the repeating features based on the remaining contours in the set of inspection contours after the filtering.

18. The system of claim 17, wherein the manufacturing variation is configured to be provided to a cost function to facilitate optimization of a patterning process.

19. The system of claim 17, wherein the one or more processors configured to determine the manufacturing variation of the repeating features are further configured to stack the remaining contours in the set of inspection contours, and statistically analyze the stacked remaining contours.

20. A non-transitory computer readable medium having instructions therein, the instructions, when executed by a computer system, configured to cause the computer system to at least:
receive substrate pattern inspection images;
determine contours in the substrate pattern inspection images to form a set of inspection contours, wherein determination of contours comprises detection of edges of features in the substrate pattern inspection images; and
filter outlier contours from the set of inspection contours.
